(19) United States
(12) Patent Application Publication
(10) Pub. No.: US 2023/0070053 A1
(43) Pub. Date: Mar. 9, 2023

(54) STIFFENER FRAME FOR SEMICONDUCTOR DEVICE PACKAGES

(71) Applicant: Applied Materials, Inc., Santa Clara, CA (US)

(72) Inventors: Han-Wen CHEN, Cupertino, CA (US); Steven VERHAVERBEKE, San Francisco, CA (US); Giback PARK, San Jose, CA (US)

(21) Appl. No.: 17/886,102

(22) Filed: Aug. 11, 2022

Related U.S. Application Data
(60) Provisional application No. 63/242,400, filed on Sep. 9, 2021.

(51) Int. Cl. H01L 23/00; H01L 23/498; H01L 23/31

(52) U.S. Cl. CPC H01L 23/562; H01L 23/49822; H01L 24/16; H01L 23/3121; H01L 2224/16227

(57) ABSTRACT

The present disclosure relates to semiconductor devices and methods of forming the same. More particularly, the present disclosure relates to semiconductor package devices having a stiffener framed formed thereon. The incorporation of the stiffener frame improves the structural integrity of the semiconductor package devices to mitigate warpage and/or collapse while simultaneously enabling utilization of thinner core substrates for improved signal integrity and power delivery between packaged devices.

### CROSS-REFERENCE TO RELATED APPLICATIONS

This application claims priority to U.S. Provisional Application Ser. No. 63/242,400, filed Sep. 9, 2021, which is herein incorporated by reference in its entirety.

### BACKGROUND

### Field

Embodiments of the present disclosure generally relate to semiconductor devices. More specifically, embodiments described herein relate to semiconductor device packages utilizing a stiffener frame and methods of forming the same.

### Description of the Related Art

Along with other ongoing trends in the development of miniaturized electronic devices and components, the demand for faster processing capabilities imposes corresponding demands on the materials, structures, and processes utilized in the fabrication of integrated circuit chips, systems, and package structures.

Conventionally, integrated circuits have been fabricated on organic substrates due to the ease of forming electrical connections therein, as well as the relatively low manufacturing costs associated with organic composites. However, as circuit densities keep increasing and electronic devices are further miniaturized, the utilization of organic substrates becomes impractical due to limitations with material structuring resolution to sustain device scaling and associated performance requirements. Furthermore, when utilized in semiconductor device packages, organic substrates present higher package stresses due to thermal expansion mismatch with semiconductor dies and other silicon-based components, which may lead to substrate flexing. And, since organic materials have relative small elastic domains, flexing thereof often leads to permanent warpage.

More recently, 2.5D and 3D integrated circuits have been fabricated utilizing silicon substrates to compensate for some of the limitations associated with organic substrates. Silicon substrate utilization is driven by the potential for high-bandwidth density, lower-power chip-to-chip communication, and heterogeneous integration sought in advanced electronic mounting and packaging applications. Yet, as thinner silicon substrates are sought to reduce lengths and distances of circuit paths and electrical connections to improve electrical performance, the reduced rigidity of the thinner silicon substrates presents similar warpage issues, particularly during assembly and test manufacturing processes.

Therefore, what is needed in the art are thin-form-factor semiconductor device package structures with increased bandwidth and rigidity, as well as methods of forming the same.

### SUMMARY

The present disclosure generally relates to electronic mounting structures and methods of forming the same.

In certain embodiments, a semiconductor device assembly is provided. The semiconductor device assembly includes a silicon core having a first side opposing a second side, wherein the silicon core has a via through the silicon core from the first side to the second side, an oxide layer on the first side and the second side, and one or more conductive interconnections through the via and having a surface exposed at the first side and the second side. The semiconductor device assembly further includes an insulating layer over the oxide layer on the first side, the second side, and within the opening, a first redistribution layer on the first side, and a silicon stiffener frame over the insulating layer and the first redistribution layer on the first side, an outer surface of the stiffener frame disposed substantially along a perimeter of the semiconductor device assembly.

In certain embodiments, a semiconductor device assembly is provided. The semiconductor device assembly includes a silicon core having a first side opposing a second side, wherein the silicon core has a via extending through the silicon core from the first side to the second side, a metal layer on the first side and the second side and electrically coupled to ground, and one or more conductive interconnections through the via and having a surface exposed at the first side and the second side. The semiconductor device assembly further includes an insulating layer over the metal layer on the first side, the second side, and within the via, a first redistribution layer on the first side, and a silicon stiffener frame over the insulating layer and the first redistribution layer on the first side, an outer surface of the stiffener frame disposed substantially along a perimeter of the semiconductor device assembly.

In certain embodiments, a semiconductor device assembly is provided. The semiconductor device assembly includes a silicon core having a first side opposing a second side, wherein the silicon core has a via extending through the silicon core from the first side to the second side, an oxide layer on the first side and the second side, and one or more conductive interconnections through the via and having a surface exposed at the first side and the second side. The semiconductor device assembly further includes an insulating layer over the oxide layer on the first side, the second side, and within the via, a first redistribution layer on the first side, and a silicon stiffener frame contacting the oxide layer on the first side of the silicon core, an outer surface of the stiffener frame disposed substantially along a perimeter of the silicon core.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1A schematically illustrates a cross-sectional side view of an example semiconductor device, according to embodiments described herein.

FIG. 1B schematically illustrates a cross-sectional side view of an example semiconductor device, according to embodiments described herein.

FIG. 1C schematically illustrates a cross-sectional side view of an example semiconductor device, according to embodiments described herein.

FIG. 1D schematically illustrates an enlarged cross-sectional side view of the example semiconductor device of FIG. 1C, according to embodiments described herein.

FIG. 1E schematically illustrates a top view of an example semiconductor device, according to embodiments described herein.

FIG. 1F schematically illustrates a top view of an example semiconductor device, according to embodiments described herein.

FIG. 1G schematically illustrates a top view of an example semiconductor device, according to embodiments described herein.

FIG. 2 is a flow diagram that illustrates a process for forming the semiconductor devices of FIGS. 1A-1D, according to embodiments described herein.

FIG. 3 is a flow diagram that illustrates a process for structuring a substrate for a semiconductor device, according to embodiments described herein.

FIGS. 4A-4D schematically illustrate cross-sectional side views of a substrate at different stages of the process depicted in FIG. 3, according to embodiments described herein.

FIG. 5 is a flow diagram that illustrates a process for forming an insulating layer on a substrate for a semiconductor core assembly, according to embodiments described herein.

FIGS. 6A-6I schematically illustrate cross-sectional side views of a substrate at different stages of the process depicted in FIG. 5, according to embodiments described herein.

FIG. 7 is a flow diagram that illustrates a process for forming an insulating layer on a substrate for a semiconductor core assembly, according to embodiments described herein.

FIGS. 8A-8E schematically illustrate cross-sectional side views of a substrate at different stages of the process depicted in FIG. 7, according to embodiments described herein

FIG. 9 is a flow diagram that illustrates a process for forming interconnections in a semiconductor core assembly, according to embodiments described herein.

FIGS. 10A-10H schematically illustrate cross-sectional side views of the semiconductor core assembly at different stages of the process depicted in FIG. 9, according to embodiments described herein.

FIG. 11 is a flow diagram that illustrates a process for forming a redistribution layer on a semiconductor core assembly, according to embodiments described herein.

FIGS. 12A-12L schematically illustrate cross-sectional side views of the semiconductor core assembly at different stages of the process depicted in FIG. 11, according to embodiments described herein.

FIG. 13 is a flow diagram that illustrates a process for forming a stiffener frame on a semiconductor core assembly, according to embodiments described herein.

FIGS. 14A-14J schematically illustrate cross-sectional side views of the semiconductor core assembly at different stages of the process depicted in FIG. 13, according to embodiments described herein

FIG. 15 schematically illustrates a cross-sectional side view of an example semiconductor device, according to embodiments described herein.

FIG. 16 schematically illustrates a cross-sectional side view of an example semiconductor device, according to embodiments described herein.

FIG. 17 schematically illustrates a cross-sectional side view of an example semiconductor device, according to embodiments described

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to semiconductor devices and methods of forming the same. More particularly, the present disclosure relates to semiconductor package devices having a stiffener framed formed thereon.

The semiconductor package devices and methods described herein may be utilized to form homogeneous and heterogeneous high-density integrated devices, including semiconductor packages, flip chip ball grid array (fcBGA or flip-chip BGA) semiconductor packages, printed circuit board (PCB) assemblies, PCB spacer assemblies, chip carrier and intermediate carrier assemblies (e.g., for graphics cards), memory stacks, and the like. In certain aspects, the devices and methods disclosed are intended to replace more conventional fcBGA package structures, which are limited by the intrinsic properties of the materials typically utilized to form these various structures. In particular, conventional fcBGA package structures may present greater mechanical stresses caused by thermal expansion mismatch between components thereof, leading to high rates of substrate flexing, warpage, and/or collapse. Such stresses are further amplified as substrates for these devices are scaled for improved signal integrity and power delivery, resulting in lesser structural stability thereof. Accordingly, the devices and methods disclosed herein provide semiconductor package devices that overcome many of the disadvantages associated with conventional fcBGA package structures described above.

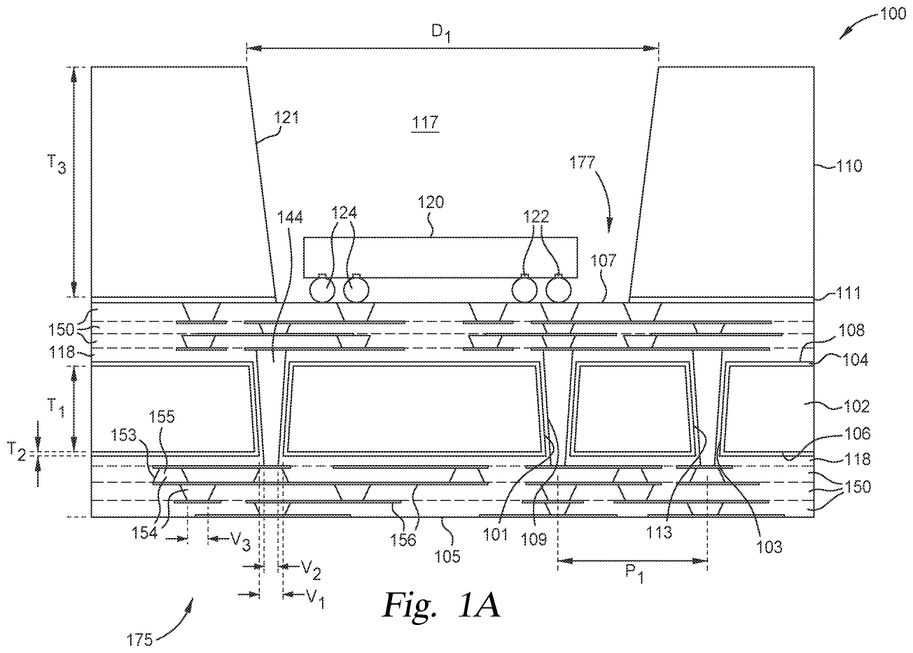

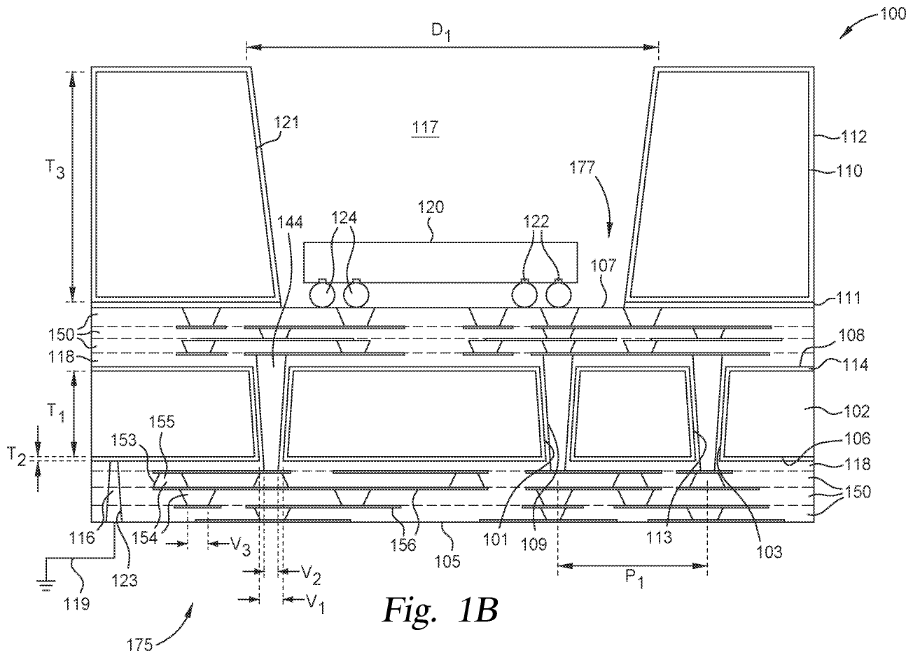

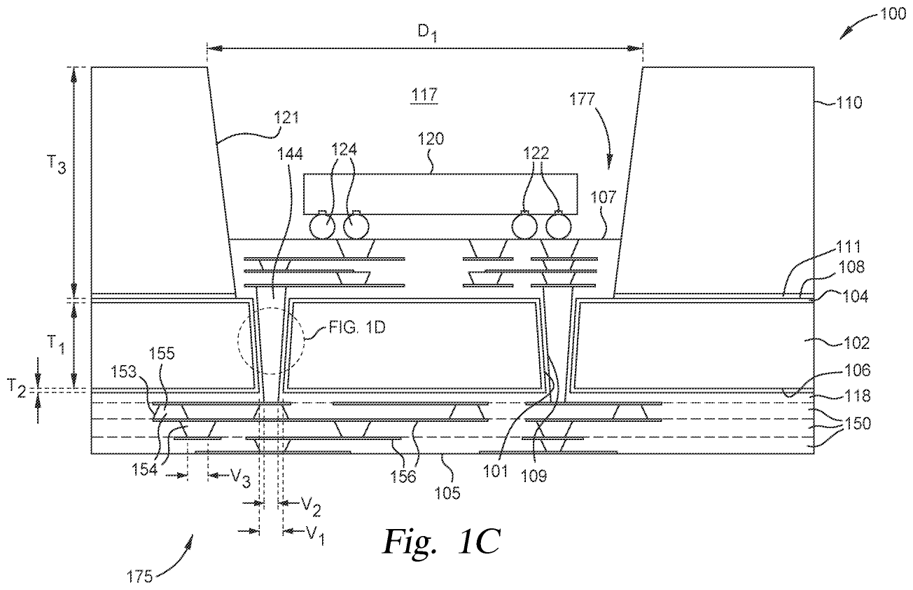

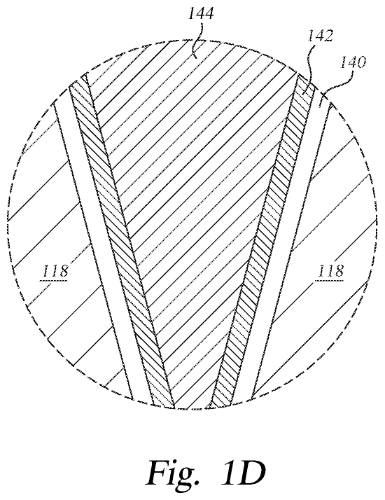

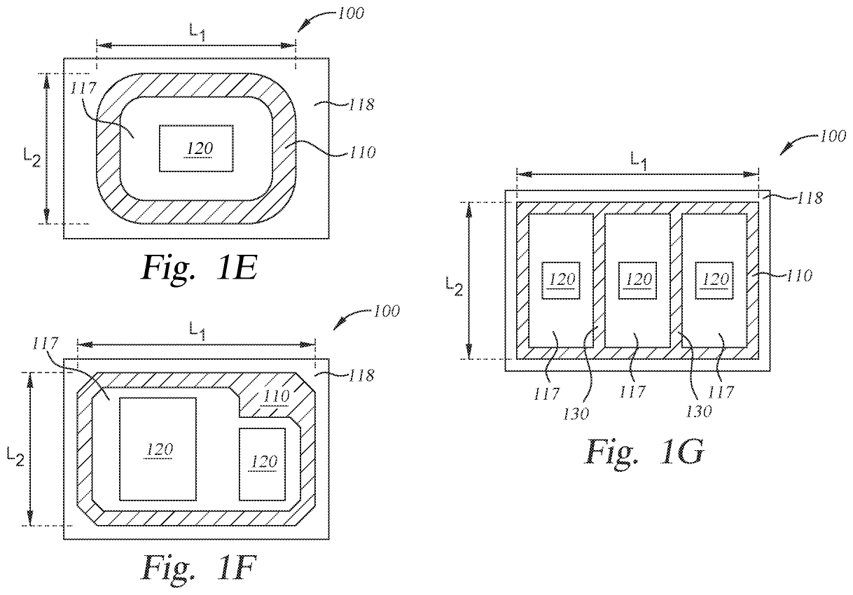

FIGS. 1A-1D illustrate cross-sectional side views of different configurations of a thin-form-factor semiconductor core assembly 100, according to certain embodiments of the present disclosure. The semiconductor core assembly 100 may be utilized for structural support and electrical interconnection of semiconductor packages or other devices, which may be mounted thereto utilizing any suitable technique, e.g., flip-chip or wafer bumping. In certain examples, the semiconductor core assembly 100 may be utilized as a carrier structure for a surface-mounted device, such as a chip or graphics card. The semiconductor core assembly 100 generally includes a core substrate 102, an optional passivating layer 104 (shown in FIGS. 1A and 1C) or metal cladding layer 114 (shown in FIG. 1B), an insulating layer 118, and a stiffener frame 110.

In certain embodiments, the core substrate 102 includes a patterned (e.g., structured) substrate formed of any suitable substrate material. For example, the core substrate 102 includes a substrate formed from a III-V compound semiconductor material, silicon (e.g., having a resistivity between about 1 and about 10 Ohm-com or conductivity of about 100 W/mK), crystalline silicon (e.g., Si<100> or Si<111>), silicon oxide, silicon germanium, doped or undoped silicon, undoped high resistivity silicon (e.g., float zone silicon having lower dissolved oxygen content and a resistivity between about 5000 and about 10000 ohm-cm), doped or undoped polysilicon, silicon nitride, silicon carbide (e.g., having a conductivity of about 500 W/mK), quartz, glass (e.g., borosilicate glass), sapphire, alumina, and/or ceramic materials. In certain embodiments, the core substrate 102 includes a monocrystalline p-type or n-type silicon substrate. In certain embodiments, the core substrate 102 includes a polycrystalline p-type or n-type silicon substrate. In another embodiment, the core substrate 102 includes a p-type or an n-type silicon solar substrate. Generally the substrate utilized to form the core substrate 102 may have a polygonal or circular shape. For example, the core substrate 102 may include a substantially square silicon substrate having lateral dimensions between about 120 mm and about 180 mm, such as about 150 mm or between about 156 mm and about 166 mm, with or without chamfered edges. In another example, the core substrate 102 may include a circular silicon-containing wafer having a diameter between about 20 mm and about 700 mm, such as between about 100 mm and about 500 mm, for example about 200 mm or about 300 mm.

The core substrate 102 has a thickness T₁ between about 50 μm and about 1500 μm, such as a thickness T₁ between about 90 μm and about 780 μm. For example, the core substrate 102 has a thickness T₁ between about 100 μm and about 300 μm, such as a thickness T₁ between about 110 μm and about 200 μm, such as a thickness T₁ of about 170 μm. In another example, the core substrate 102 has a thickness T₁ between about 70 μm and about 150 μm, such as a thickness T₁ between about 100 μm and about 130 μm. In another example, the core substrate 102 has a thickness T₁ between about 700 μm and about 800 μm, such as a thickness T₁ between about 725 μm and about 775 μm.

The core substrate 102 further includes one or more through-substrate vias 103 (e.g., through-holes) formed therein to enable conductive electrical interconnections to be routed through the core substrate 102. Generally, the one or more through-substrate vias 103 are substantially cylindrical in shape. However, other suitable morphologies for the through-substrate vias 103 are also contemplated. The through-substrate vias 103 may be formed as singular and isolated through-substrate vias 103 through the core substrate 102, or in one or more groupings or arrays. In certain embodiments, a minimum pitch Pi (e.g., via center to via center) between each via 103 is less than about 1000 μm, such as between about 25 μm and about 200 μm. For example, the pitch Pi is between about 40 μm and about 150 μm, such as between about 100 μm and about 140 μm, such as about 120 μm. In certain embodiments, the one or more through-substrate vias 103 have a diameter V₁ less than about 500 μm, such as a diameter V₁ less than about 250 μm. For example, the through-substrate vias 103 have a diameter V₁ between about 25 μm and about 100 μm, such as a diameter V₁ between about 30 μm and about 60 μm. In certain embodiments, the through-substrate vias 103 have a diameter V₁ of about 40 μm.

The optional passivating layer 104 of FIGS. 1A and 1C may be formed on one or more surfaces of the core substrate 102, including a first surface 108, a second surface 106, and one or more sidewalls 101 of the through-substrate vias 103. In certain embodiments, the passivating layer 104 is formed on substantially all exterior surfaces of the core substrate 102 such that the passivating layer 104 substantially surrounds the core substrate 102. Thus, the passivating layer 104 provides a protective outer barrier layer for the core substrate 102 against corrosion and other forms of damage. In certain embodiments, the passivating layer 104 includes an oxide film or layer, such as a thermal oxide layer. In some examples, the passivating layer 104 has a thickness between about 100 nm and about 3 μm, such as a thickness between about 200 nm and about 2.5 μm. In one example, the passivating layer 104 has a thickness between about 300 nm and about 2 μm, such as a thickness of about 1.5 μm.

In the embodiments shown in FIG. 1B, the core substrate 102 includes the metal cladding layer 114 in place of the passivating layer 104, which may be formed on one or more surfaces thereof, including the first surface 108, the second surface 106, and the one or more sidewalls 101 of the through-substrate vias 103. In certain embodiments, the metal cladding layer 114 is formed on substantially all exterior surfaces of the core substrate 102 such that the metal cladding layer 114 substantially surrounds the core substrate 102. The metal cladding layer 114 acts as a reference layer (e.g., grounding layer or a voltage supply layer) and is disposed on the core substrate 102 to protect subsequently formed interconnections from electromagnetic interference and also shield electric signals from the semiconductor material (Si) that is used to form the core substrate 102. In certain embodiments, the metal cladding layer 114 includes a conductive metal layer that includes nickel, aluminum, gold, cobalt, silver, palladium, tin, or the like. In certain embodiments, the metal cladding layer 114 includes a metal layer that includes an alloy or pure metal that includes nickel, aluminum, gold, cobalt, silver, palladium, tin, or the like. The metal cladding layer 114 generally has thickness between about 50 nm and about 10 μm such as between about 100 nm and about 5 μm.

The insulating layer 118 is formed on one or more surfaces of the core substrate 102, the passivating layer 104, or the metal cladding layer 114 and may substantially encase the passivating layer 104, the metal cladding layer 114, and/or the core substrate 102. Thus, the insulating layer 118 may extend into the through-substrate vias 103 and coat the passivating layer 104 or the metal cladding layer 114 formed on the sidewalls 101, or directly coat the core substrate 102, thus defining the diameter V₂ as depicted in FIG. 1A. In certain embodiments, the insulating layer 118 has a thickness T₂ from an outer surface of the core substrate 102, the passivating layer 104, or the metal cladding layer 114 to an adjacent outer surface of the insulating layer 118 (e.g., major surfaces 105, 107) that is less than about 50 μm, such as a thickness T₂ less than about 20 μm. For example, the insulating layer 118 has thickness T₂ between about 5 μm and about 10 μm.

In certain embodiments, the insulating layer 118 is formed of polymer-based dielectric materials. For example, the insulating layer 118 is formed from a flowable build-up material. Accordingly, although hereinafter referred to as an “insulating layer,” the insulating layer 118 may also be described as a dielectric layer. In a further embodiment, the insulating layer 118 is formed of an epoxy resin material having a ceramic filler, such as silica (SiO₂) particles. Other examples of ceramic fillers that may be utilized to form the insulating layer 118 include aluminum nitride (AlN), aluminum oxide (Al₂O₃), silicon carbide (SiC), silicon nitride (Si₃N₄, Sr₂Ce₂Ti₅O₁₆, zirconium silicate (ZrSiO₄), wollastonite (CaSiO₃), beryllium oxide (BeO), cerium dioxide (CeO₂), boron nitride (BN), calcium copper titanium oxide (CaCu₃Ti₄O₁₂), magnesium oxide (MgO), titanium dioxide (TiO₂), zinc oxide (ZnO) and the like. In some examples, the ceramic fillers utilized to form the insulating layer 118 have particles ranging in size between about 40 nm and about 1.5 μm, such as between about 80 nm and about 1 μm. For example, the ceramic fillers have particles ranging in size between about 200 nm and about 800 nm, such as between about 300 nm and about 600 nm. In some embodiments, the ceramic fillers include particles having a size less than about 10% of the width or diameter of adjacent through-substrate vias 103 in the core substrate 102, such as a size less than about 5% of the width or diameter of the through-substrate vias 103.

One or more through-assembly vias 113 are formed through the insulating layer 118 where the insulating layer 118 extends into the through-substrate vias 103. For example, the through-assembly vias 113 may be centrally formed within the through-substrate vias 103 and surrounded by the insulating layer 118 disposed therein, thus creating a “via-in-via” structure. Accordingly, the insulating layer 118 forms one or more sidewalls 109 of the through-assembly vias 113, wherein the through-assembly vias 113 have a diameter V₂ lesser than the diameter V₁ of the through-substrate vias 103. In certain embodiments, the through-assembly vias 113 have a diameter V₂ less than about 100 μm, such as less than about 75 μm. For example, the through-assembly vias 113 have a diameter V₂ less than about 50 μm, such as less than about 35 μm. In certain embodiments, the through-assembly vias 113 have a diameter of between about 25 μm and about 50 μm, such as a diameter of between about 35 μm and about 40 μm.

The through-assembly vias 113 provide channels through which one or more electrical interconnections 144 are formed in the semiconductor core assembly 100. In certain embodiments, the electrical interconnections 144 are formed through a portion of the thickness of the semiconductor core assembly 100, as shown in FIGS. 1A-1C. In certain other embodiments, the electrical interconnections 144 are formed through the entire thickness of the semiconductor core assembly 100 (i.e. from the first major surface 105 to the second major surface 107 of the semiconductor core assembly 100), and have a longitudinal length corresponding to a total thickness of the semiconductor core assembly 100. In further embodiments, the electrical interconnections 144 may protrude from a major surface of the semiconductor core assembly 100, such as the major surfaces 105, 107 as depicted in FIG. 1A. Generally, the electrical interconnections may have a longitudinal length between about 50 μm and about 1000 μm, such as a longitudinal length between about 200 μm and about 800 μm. In one example, the electrical interconnections 144 have a longitudinal length of between about 400 μm and about 600 μm, such as longitudinal length of about 500 μm. The electrical interconnections 144 may be formed of any conductive materials used in the field of integrated circuits, circuit boards, chip carriers, and the like. For example, the electrical interconnections 144 are formed of a metallic material, such as copper, aluminum, gold, nickel, silver, palladium, tin, or the like.

In certain embodiments, the electrical interconnections 144 have a lateral thickness equal to the diameter V₂ of the through-assembly vias 113 in which they are formed. In certain embodiments, the semiconductor core assembly 100 further includes an adhesion layer 140 and/or a seed layer 142 formed thereon for electrical isolation of the electrical interconnections 144, shown in FIG. 1D. In certain embodiments, the adhesion layer 140 is formed on surfaces of the insulating layer 118 adjacent to the electrical interconnections 144, including the sidewalls of the through-assembly vias 113. Thus, as depicted in FIG. 1C, the electrical interconnections 144 have a lateral thickness less than the diameter V₂ of the through-assembly vias 113 in which they are formed. In yet another embodiment, the electrical interconnections 144 only cover the surfaces of the sidewalls of the through-assembly vias 113, and thus may have a hollow core therethrough.

The adhesion layer 140 may be formed of any suitable materials, including but not limited to titanium, titanium nitride, tantalum, tantalum nitride, manganese, manganese oxide, molybdenum, cobalt oxide, cobalt nitride, and the like. In certain embodiments, the adhesion layer 140 has a thickness between about 10 nm and about 300 nm, such as between about 50 nm and about 150 nm. For example, the adhesion layer 140 has a thickness between about 75 nm and about 125 nm, such as about 100 nm.

The optional seed layer 142 comprises a conductive material, including but not limited to copper, tungsten, aluminum, silver, gold, or any other suitable materials or combinations thereof. The seed layer 142 may be formed on the adhesion layer 140 or directly on the sidewalls of the through-assembly vias 113 (e.g., on the insulating layer 118 without an adhesion layer therebetween). In certain embodiments, the seed layer 142 has a thickness between about 50 nm and about 500 nm, such as between about 100 nm and about 300 nm. For example, the seed layer 142 has a thickness between about 150 nm and about 250 nm, such as about 200 nm.

In certain embodiments, the semiconductor core assembly 100 further includes one or more redistribution layers 150 formed on a first side 175 and/or a second side 177 of the semiconductor core assembly 100. In certain embodiments, the redistribution layers 150 are formed of substantially the same materials as the insulating layer 118 (e.g., polymer-based dielectric materials), and thus forms an extension thereof. In other embodiments, the redistribution layers 150 are formed of a different material than the insulating layer 118. For example, the redistribution layers 150 may be formed of a photodefinable polyimide material, a non-photosensitive polyimide, polybenzoxazole (PBO), benzocyclobutene (BCB), silicon dioxide, and/or silicon nitride. In another example, the redistribution layers 150 are formed from a different inorganic dielectric material than the insulating layer 118. In yet another example, one or more of the outermost redistribution layers 150 includes a solder layer, upon which the stiffener frame 110 (discussed below) may be attached). In certain embodiments, the redistribution layers 150 have a thickness between about 5 μm and about 50 μm each, such as a thickness between about 10 μm and about 40 μm each. For example, the redistribution layers 150 have a thickness between about 20 μm and about 30 μm each, such as about 25 μm each.

The redistribution layers 150 may include one or more vertical redistribution connections 154 formed through redistribution vias 153, as well as lateral redistribution connections 156, for relocating contact points of the electrical interconnections 144 to desired locations on the surfaces of the semiconductor core assembly 100, such as the major surfaces 105, 107. In some embodiments, the redistribution layer 150 may further include one or more external electrical connections (not shown) formed on the major surfaces 105, 107, such as a ball grid array or solder balls. Generally, the redistribution vias 153 and the vertical redistribution connections 154 have substantially similar or smaller lateral dimensions relative to the through-assembly vias 113 and the electrical interconnections 144, respectively. For example, the redistribution vias 153 have a diameter V₃ between about 2 μm and about 50 μm, such as a diameter V₃ between about 10 μm and about 40 μm, such as a diameter V₃ between about 20 μm and about 30 μm. Furthermore, the redistribution layer 150 may include the adhesion layer 140 and the seed layer 142 formed on surfaces adjacent to the vertical redistribution connections 154 and lateral redistribution connections 156, including sidewalls of the redistribution vias 153.

In embodiments where the core substrate 102 includes the metal cladding layer 114, such as in FIG. 1B, the metal cladding layer 114 is further coupled to at least one cladding connection 116 forming a connection point on at least one side of the semiconductor core assembly 100. In certain embodiments, the metal cladding layer 114 is coupled to two cladding connections 116 formed on opposing sides of the semiconductor core assembly 100 (not shown). The cladding connections 116 may be connected to a common ground, such as exemplary ground 119, used by one or more the semiconductor devices stacked with (e.g., above or below) the semiconductor core assembly 100. Alternatively, the cladding connections 116 are connected to a reference voltage, such as a power voltage. As depicted, the cladding connections 116 are formed in the insulating layer 118 and connect the metal cladding layer 114 to connection ends of the cladding connections 116 that are disposed on or at the surface of the semiconductor core assembly 100, such as major surfaces 107 and 105, so that the metal cladding layer 114 can be connected to an external common ground or reference voltage (shown in FIG. 1B as an exemplary connection to ground 119).

The metal cladding layer 114 may be electrically coupled to external ground 119 via the cladding connections 116 and any other suitable coupling means. For example, the cladding connections 116 may be indirectly coupled to external ground 119 by solder bumps on opposing sides of the semiconductor core assembly 100. In certain embodiments, the cladding connections 116 may be first routed through a separate electronic system or device before coupling to the external ground 119. The utilization of a grounding pathway between the metal cladding layer 114 and the external ground 119 reduces or eliminates interference between interconnections 144 and/or redistribution connections 154, 156 and prevents shorting of integrated circuits coupled thereto, which may damage the semiconductor core assembly 100 and any systems or devices integrated or stacked therewith.

Similar to the electrical interconnections 144 and redistribution connections 154, 156, the cladding connections 116 are formed of any suitable conductive material, including but not limited to nickel, copper, aluminum, gold, cobalt, silver, palladium, tin, or the like. The cladding connections 116 are deposited or plated through cladding vias 123 that are substantially similar to the through-assembly vias 113 or redistribution vias 153 but only traverse a portion of the semiconductor core assembly 100 (e.g., from a surface thereof to the core substrate 102. Accordingly, the cladding vias 123 may be formed through the insulating layer 118 directly above or below the core substrate 102 having the metal cladding layer 114 formed thereon. Furthermore, like the electrical interconnections 144 and redistribution connections 154, 156, the cladding connections 116 may completely fill the cladding vias 123 or line the inner circumferential walls thereof, thus having a hollow core.

In certain embodiments, the cladding vias 123 and the cladding connections 116 have lateral dimensions (e.g., a diameter and lateral thickness, respectively) substantially similar to the diameter V₂. In certain embodiments, the adhesion layer 140 and seed layer 142 are formed on the cladding vias 123, and so the cladding vias 123 may have a diameter substantially similar to the diameter V₂, while the cladding connections 116 may have a lateral thickness less than the diameter V₂ (e.g., such as a lateral thickness substantially similar to the diameter V₃). In certain embodiments, the cladding vias 123 have a diameter of about 5 μm.

As further shown in FIGS. 1A-1C, the semiconductor core assembly 100 includes the stiffener frame 110 formed on the first side 175 and/or second side 177 thereof. The stiffener frame 110 provides additional rigidity to the overall structure of semiconductor core assembly 100, thus reducing or eliminating the risk of warpage or collapse of core substrate 102 during integration of semiconductor core assembly 100 into high-density integrated devices (e.g., semiconductor packages, PCB assemblies, PCB spacer assemblies, chip carrier assemblies, intermediate carrier assemblies, memory stacks, etc.). Integrating the stiffener frame 110 with the semiconductor core assembly 100 thus enables the utilization of thinner core substrates 102, which facilitates improved signal integrity and power delivery between components on either side of the core substrates 102. In certain embodiments, the stiffener frame 110 may also provide a shielding effect for one or more semiconductor dies integrated with semiconductor core assembly 100, such as the semiconductor dies 120 shown in FIGS. 1A-1C.

Generally, the stiffener frame 110 has a polygonal or circular ring-like shape and is formed from a patterned substrate comprising any suitable substrate material. In certain embodiments, the stiffener frame 110 may be formed from a substrate comprising a material substantially similar to that of core substrate 102, thus matching the coefficient of thermal expansion (CTE) thereof and reducing or eliminating the risk of warpage during assembly. For example, the stiffener frame 110 may be formed from a III-V compound semiconductor material, silicon (e.g., having a resistivity between about 1 and about 10 Ohm-com or conductivity of about 100 W/mK), crystalline silicon (e.g., Si<100> or Si<111>), silicon oxide, silicon germanium, doped or undoped silicon, undoped high resistivity silicon (e.g., float zone silicon having lower dissolved oxygen content and a resistivity between about 5000 and about 10000 ohm-cm), doped or undoped polysilicon, silicon nitride, silicon carbide (e.g., having a conductivity of about 500 W/mK), quartz, glass (e.g., borosilicate glass), sapphire, alumina, and/or ceramic materials. In certain embodiments, the stiffener frame 110 includes monocrystalline p-type or n-type silicon. In certain embodiments, the stiffener frame 110 includes polycrystalline p-type or n-type silicon.

The stiffener frame 110 has a thickness T₃ between about 50 μm and about 1500 μm, such as a thickness T₃ between about 100 μm and about 1200 μm. For example, the stiffener frame 110 has a thickness T₃ between about 200 μm and about 1000 μm, such as a thickness T₃ between about 400 μm and about 800 μm, such as a thickness T₃ of about 775 μm. In another example, the stiffener frame 110 has a thickness T₃ between about 100 μm and about 700 μm, such as a thickness T₃ between about 200 μm and about 500 μm. In another example, the stiffener frame 110 has a thickness T₃ between about 800 μm and about 1400 μm, such as a thickness T₃ between about 1000 μm and about 1200 μm. In yet another example, the stiffener frame 110 has a thickness greater than about 1200 μm.

The stiffener frame 110 may be attached to the semiconductor core assembly 100 via any suitable methods. For example, as shown in FIGS. 1A-1C, the stiffener frame 110 may be attached to the semiconductor core assembly 100 via an adhesive 111, which may include a laminated adhesive material, die attach film, adhesive film, glue, wax, or the like. In certain embodiments, adhesive 111 is a layer of uncured dielectric material similar to that of insulating layer 118, such as an epoxy resin material having a ceramic filler. In certain embodiments, the stiffener frame 110 is attached to the insulating layer 118 on major surface 105 or 107 (FIGS. 1A-1B). In certain other embodiments, the stiffener frame 110 is attached to the core substrate 102, e.g., on surface 108 or 106, or attached to the passivating layer 104 or metal cladding layer 114 (FIG. 1C). In such embodiments, desired portions of the insulating layer 118 may be removed via, e.g., laser ablation, to enable attachment of the stiffener frame 110 to the core substrate 102.

As described above, the stiffener frame 110 is patterned to form one or more openings 117 therethrough, which may, in certain embodiments, receive one or more semiconductor dies 120 (or other devices) therein. Accordingly, the openings 117 enable integration (e.g., stacking) of semiconductor dies 120 directly onto either the insulating layer 118 or core substrate 102 of semiconductor core assembly 100, without requiring further extension of interconnections through stiffener frame 110. In further embodiments, the stiffener frame 110 may also provide a mechanical and/or electrical shielding effect for the dies 120. For example, as shown in FIG. 1B, the stiffener frame 110 may include a metal cladding layer 112 formed thereon and connected to ground 115, which may provide an electromagnetic interference (EMI) shielding effect for dies 120 disposed within openings 117. In such embodiments, the metal cladding layer 112 may comprise substantially the same materials and be formed via substantially similar processes to metal cladding layer 114. For example, metal cladding layer 112 may be formed of nickel displacement plating or other electroless or electrolytic plating processes. In certain embodiments, the stiffener frame 110 is formed of high resistivity silicon and acts as an insulator for semiconductor core assembly 100.

The one or more openings 117 may have any suitable morphologies and dimensions for accommodating, e.g., semiconductor dies 120 or other desired devices therein. For example, in certain embodiments, the openings 117 may have a substantially quadrilateral or polygonal shape. In certain embodiments, the openings 117 may have a substantially circular or irregular shape. In certain embodiments, one or more of the openings 117 have sidewalls 121 that are substantially tapered (i.e., angled), as shown in FIG. 1A-1C, substantially vertical (e.g., normal relative to, e.g., surface 107).

In certain embodiments, one or more openings 117 have a lateral dimension Di ranging between about 0.5 mm and about 50 mm, such as a lateral dimension Di ranging between about 3 mm and about 12 mm, such as a lateral dimension Di ranging between about 8 mm and about 11 mm, which may depend on the size and number of semiconductor dies 120 or other devices to be placed therein during package or system fabrication. The semiconductor dies 120 generally include a plurality of integrated electronic circuits that are formed on and/or within a substrate material, such as a piece of semiconductor material. In certain embodiments, the openings 117 are sized to have lateral dimensions substantially similar to that of the semiconductor dies 120 to be placed therein. For example, each opening 117 may be formed having lateral dimensions exceeding those of the semiconductor die(s) 120 by less than about 150 μm, such as less than about 120 μm, such as less than 100 μm

The semiconductor dies 120 may be any suitable type of die or chip, including a memory die, a microprocessor, a complex system-on-a-chip (SoC), or a standard die. Suitable types of memory dies include DRAM dies or NAND flash dies. In further examples, the semiconductor dies 120 include digital dies, analog dies, or mixed dies. Generally, the semiconductor dies 120 may be formed of a material substantially similar to that of the core substrate 102 and/or the stiffener frame 110, such as a silicon material. Utilizing semiconductor dies 120 formed of the same or similar materials of the core substrate 102 and/or the stiffener frame 110 facilitates matching of CTE therebetween, fundamentally eliminating the occurrence of warpage during assembly.

As shown in FIGS. 1A-1C, each semiconductor die 120 is disposed adjacent to one of the major surfaces 105, 107 of the semiconductor core assembly 100, and has contacts 122 thereof electrically coupled to one or more redistribution connections 154, 156 via solder bumps 124. In certain embodiments, the contacts 122 and/or the solder bumps 124 are formed of a substantially similar material to that of the interconnections 144 and the redistribution connections 154, 156. For example, the contacts 122 and the solder bumps 124 may be formed of a conductive material such as copper, tungsten, aluminum, silver, gold, or any other suitable materials or combinations thereof.

In certain embodiments, the solder bumps 124 include C4 solder bumps. In certain embodiments, the solder bumps 124 include C2 (Cu-pillar with a solder cap) solder bumps. Utilization of C2 solder bumps may enable smaller pitch lengths and improved thermal and/or electrical properties for the semiconductor core assembly 100. The solder bumps 124 may be formed by any suitable wafer bumping processes, including but not limited to electrochemical deposition (ECD) and electroplating.

FIGS. 1E-1G illustrate top views of different configurations of the thin-form-factor semiconductor core assembly 100, according to certain embodiments of the present disclosure. In particular, FIGS. 1E-1G illustrate different morphologies/arrangements of the stiffener frame 110.

In FIG. 1E, the semiconductor core assembly 100 includes a squircular (e.g., rectangle with rounded corners) ring-shaped stiffener frame 110 that surrounds a semiconductor die 120 disposed within opening 117 and substantially tracks along a lateral perimeter of the semiconductor core assembly 100. Note that although the stiffener frame 110 in FIG. 1E is illustrated with rounded corners, chamfered or right-angle corner are further contemplated.

In FIG. 1F, the stiffener frame 110 formed on the semiconductor core assembly 100 has an irregular polygonal shape to accommodate multiple semiconductor dies 120 of different sizes. A single opening 117 is formed in the stiffener frame 110, but within different lateral dimensions around each semiconductor die 120.

In FIG. 1G, the stiffener frame 110 has a rectangular ring-like shape that is partitioned by one or more transverse ribs 130 extending across the surface of the semiconductor core assembly 100, thus forming multiple openings 117 for accommodating multiple semiconductor dies 120. The formation of the ribs 130 in stiffener frame 110 may provide additional mechanical support/rigidity to the semiconductor core assembly 100. In certain embodiments, the ribs 130 may be disposed in a crossed or intersecting pattern over the semiconductor core assembly 100. Note that although the stiffener frame 110 in FIG. 1G is illustrated as rectangular with right-angle corners, other general shapes and/or corner types are further contemplated.

As shown FIGS. 1E-1G, in certain embodiments, the stiffener frame 110 may have lateral dimensions substantially matching, or substantially similar to, the semiconductor core assembly 100. Accordingly, in such embodiments, the outer lateral dimensions L₁ and L₂ are within about 500 μm of the outer lateral dimensions of the semiconductor core assembly 100, such as within about 300 μm. In certain embodiments, lateral L₁ and L₂ are substantially equal to each other.

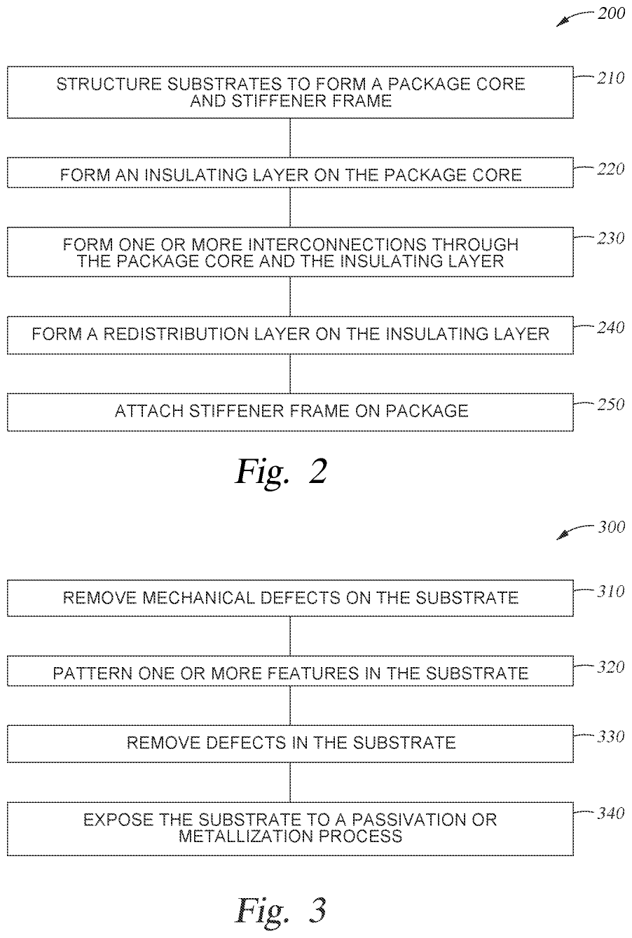

FIG. 2 illustrates a flow diagram of an exemplary method 200 of forming a semiconductor core assembly, such as semiconductor core assembly 100, according to certain embodiments of the present disclosure. The method 200 has multiple operations 210, 220, 230, 240, and 250. Each operation is described in greater detail with reference to FIGS. 3-14J. The method may include one or more additional operations which are carried out before any of the defined operations, between two of the define operations, or after all the defined operations (except where the context excludes the possibility).

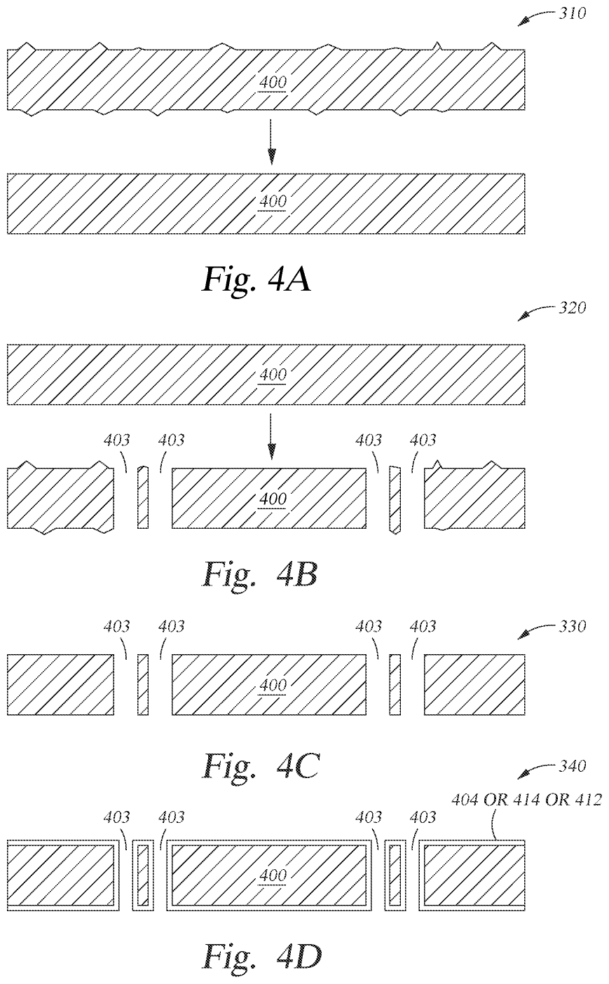

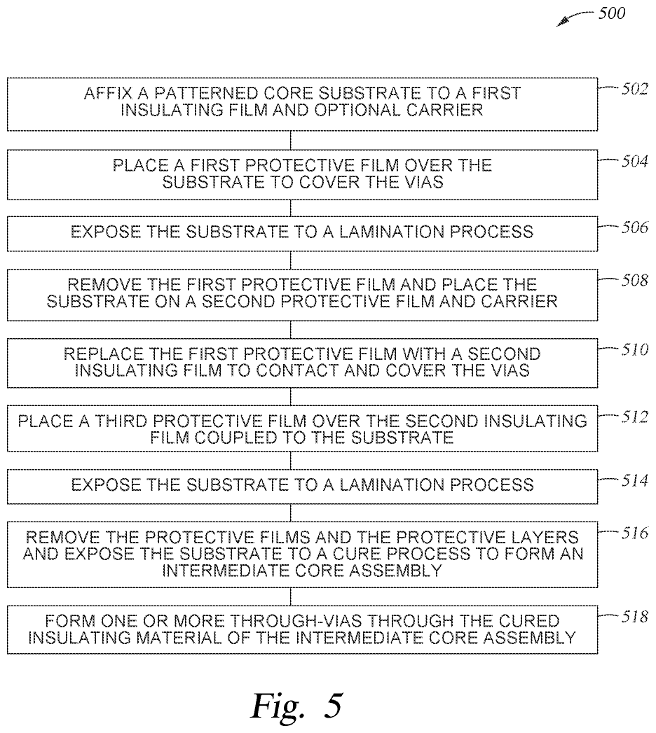

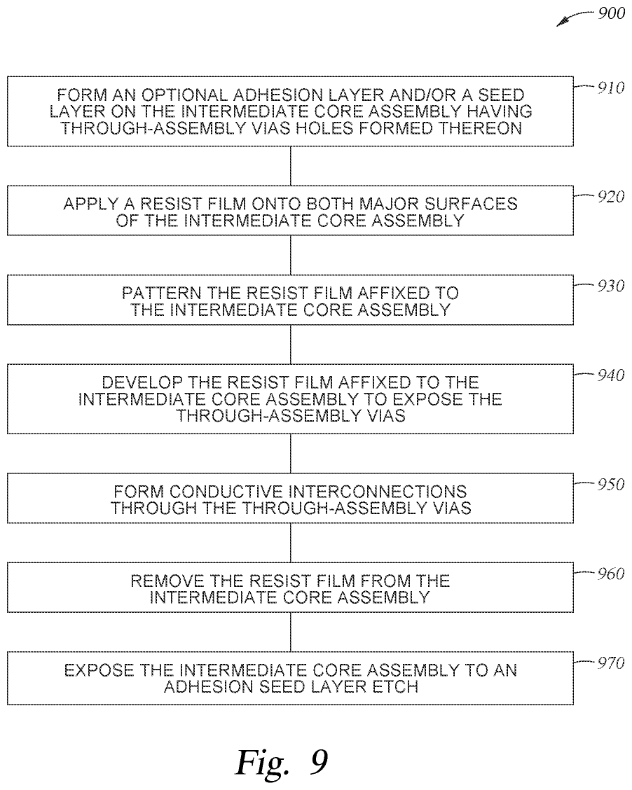

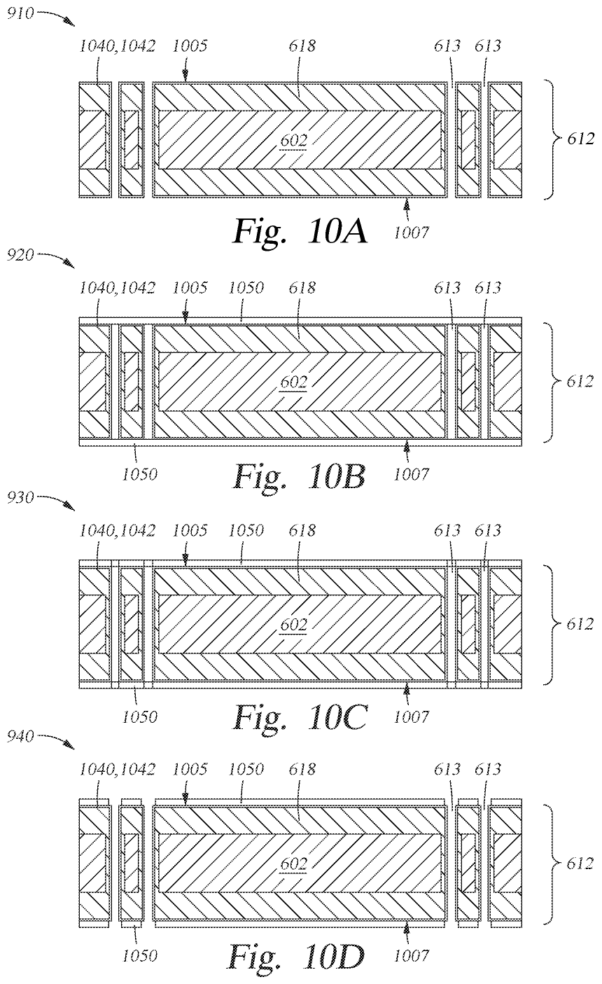

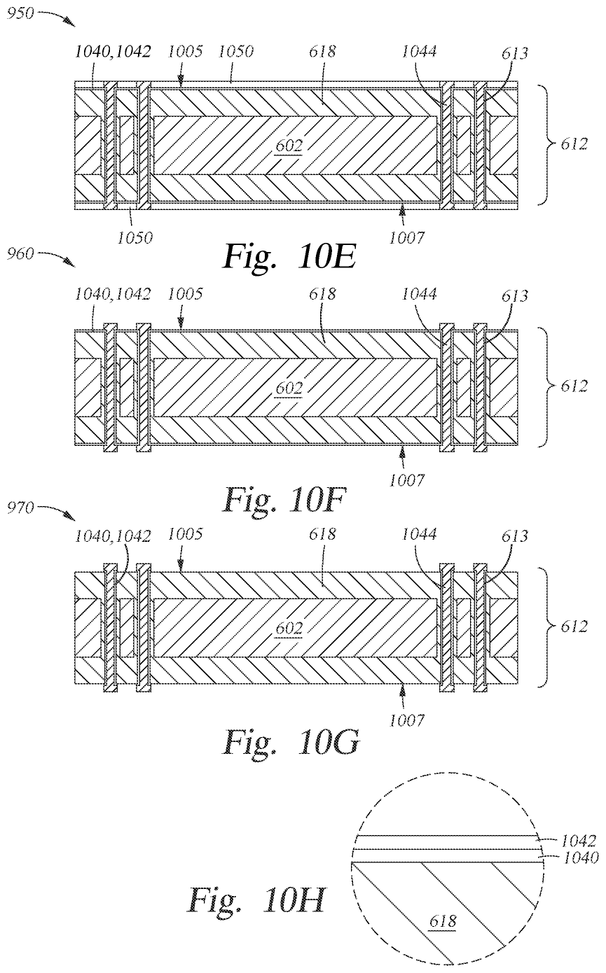

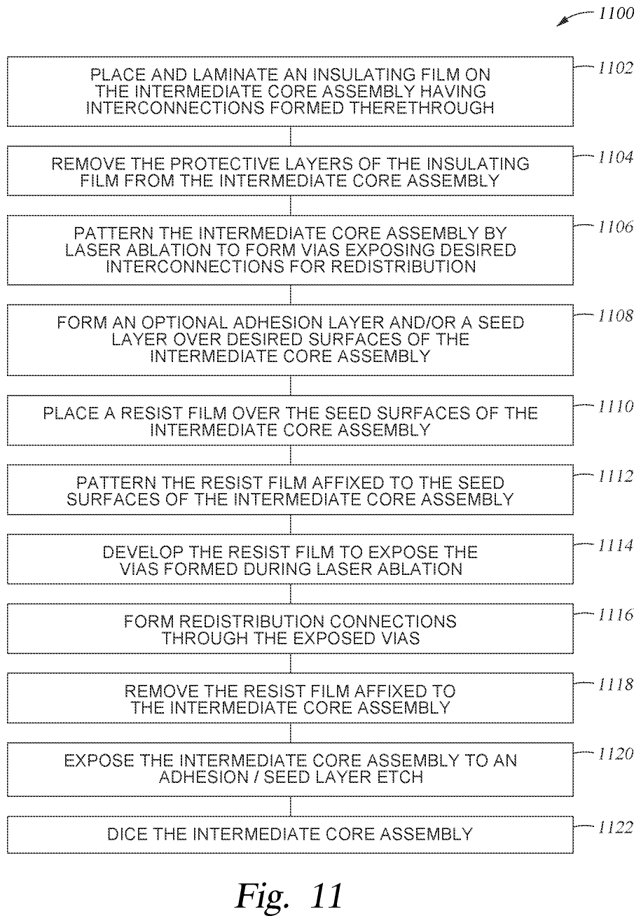

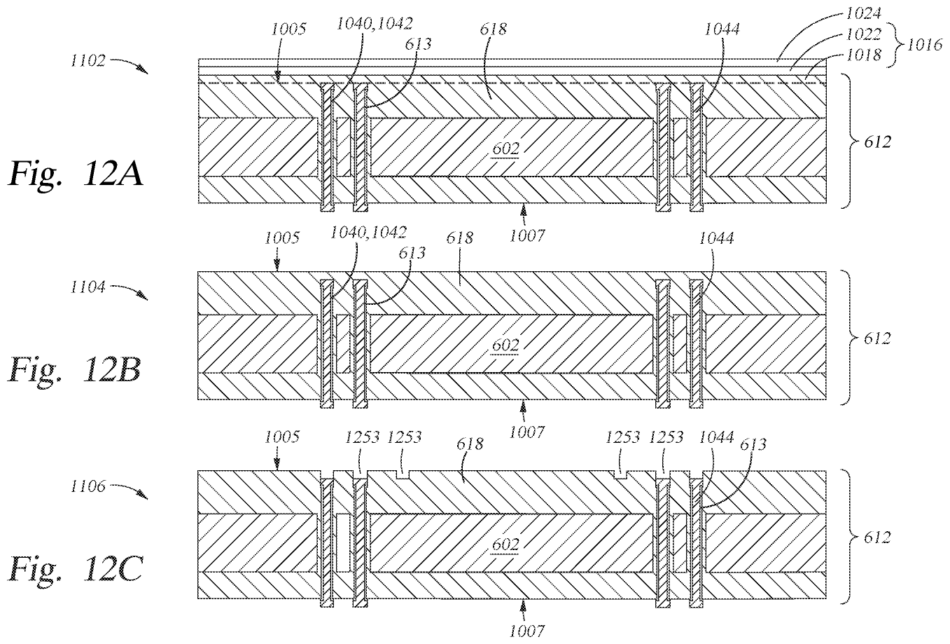

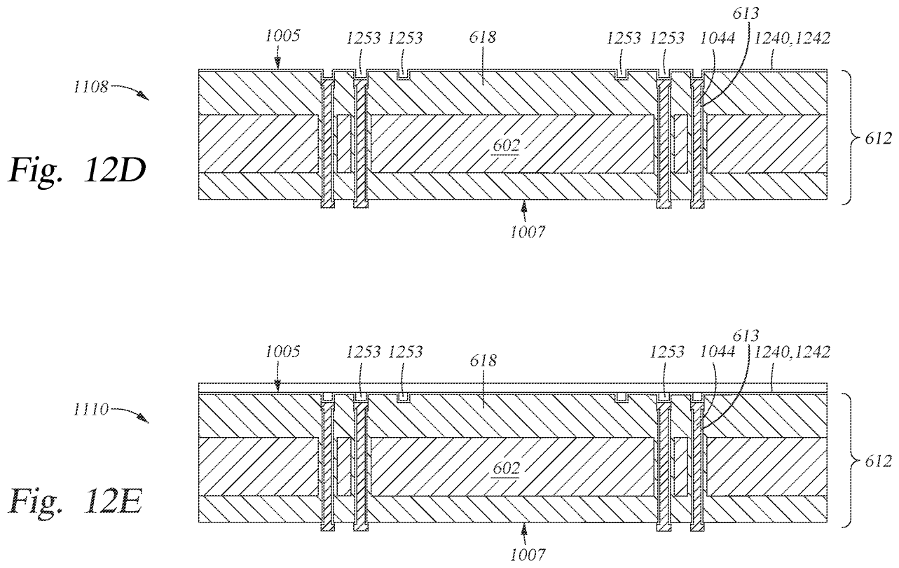

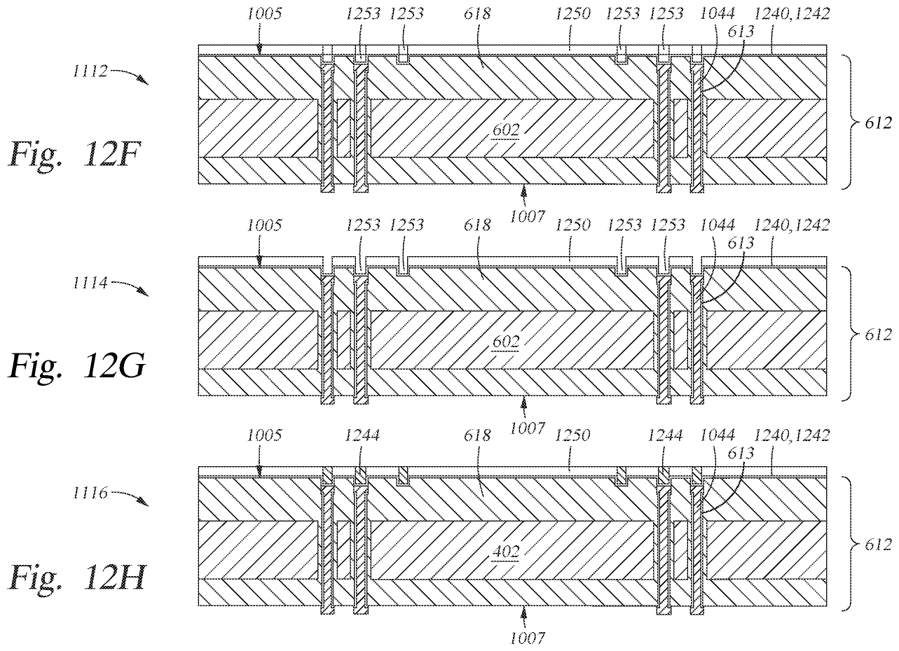

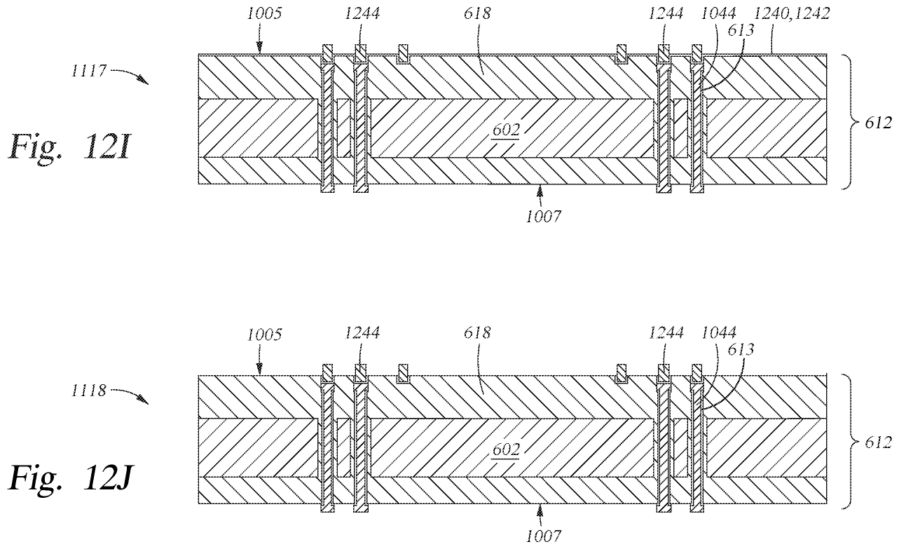

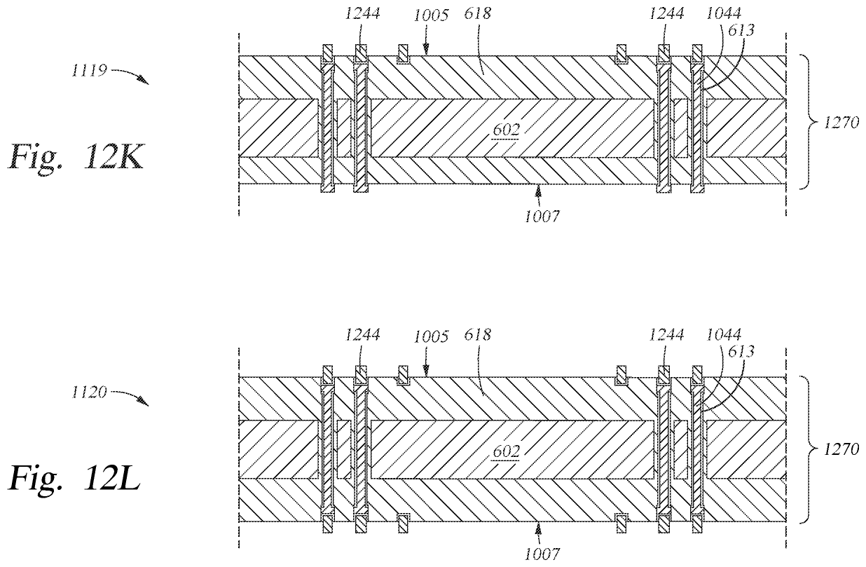

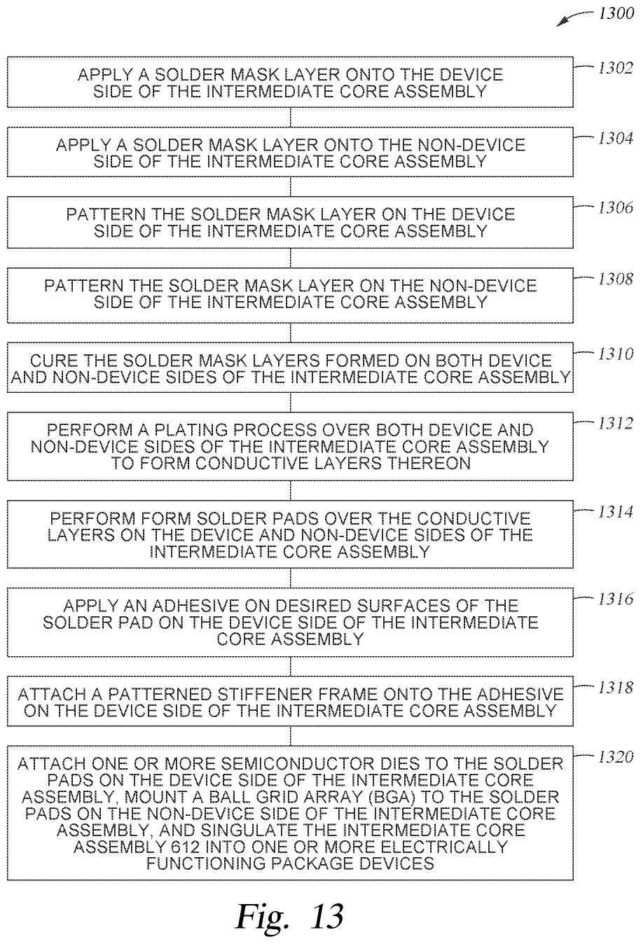

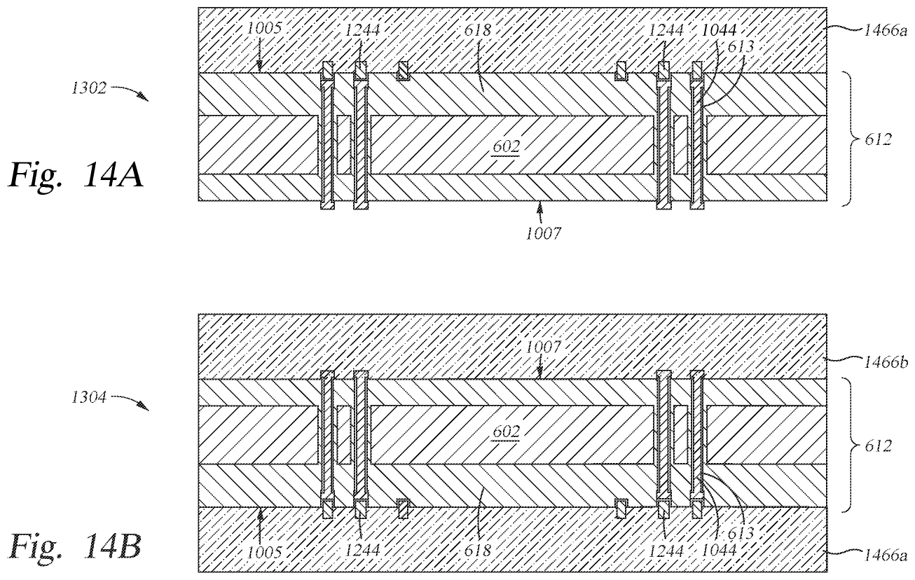

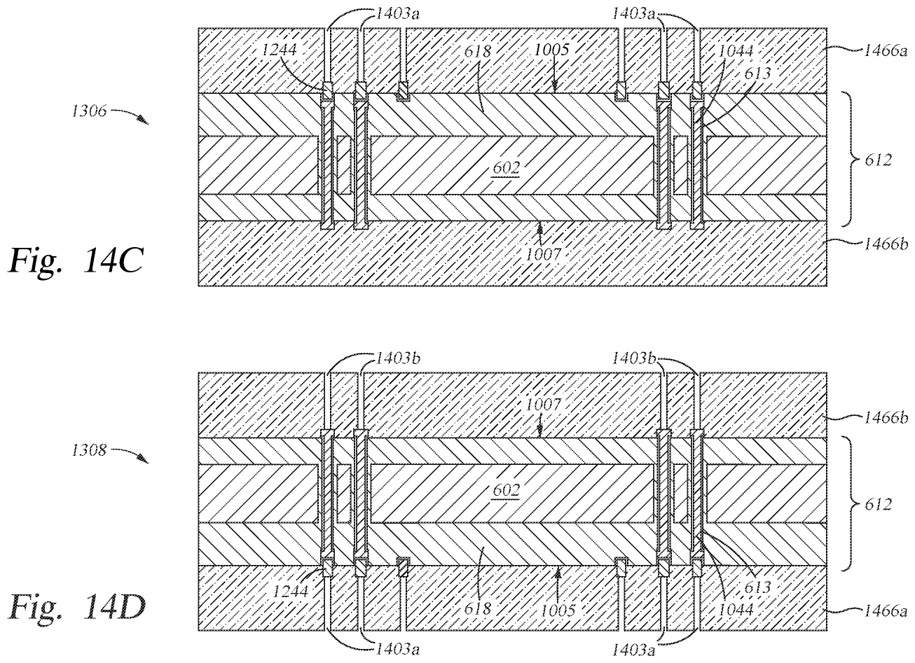

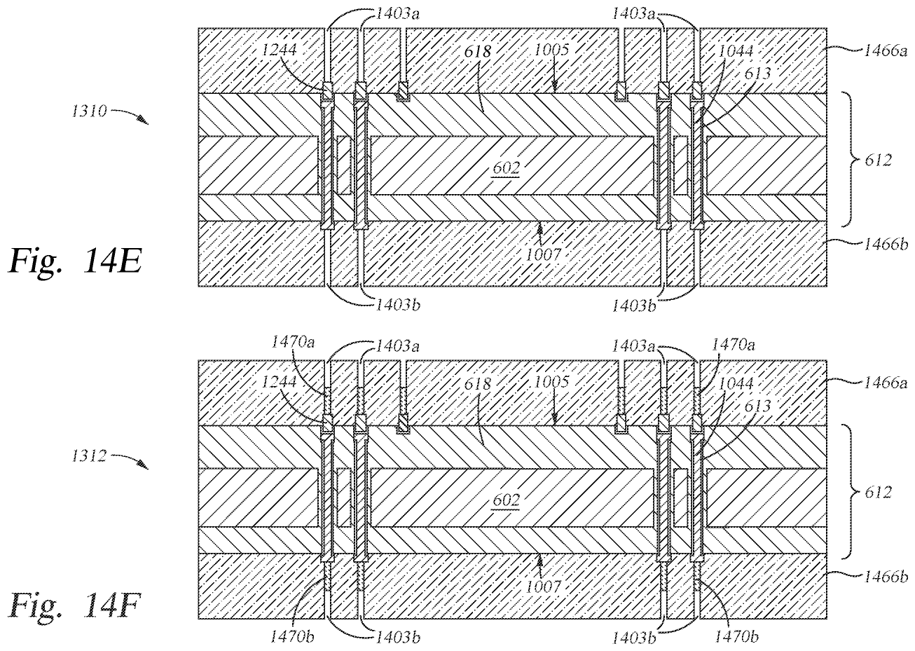

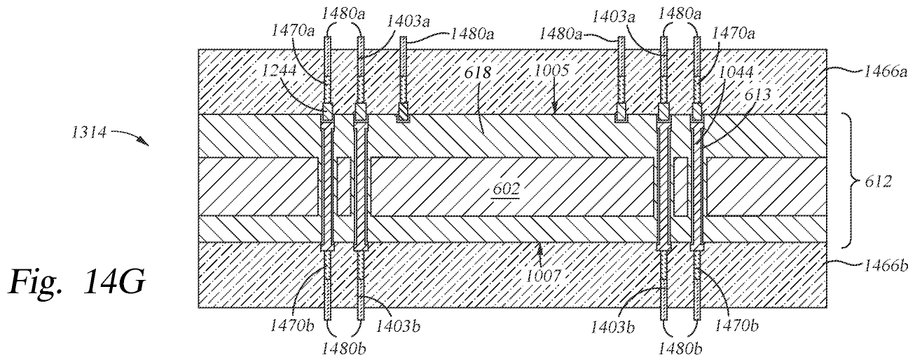

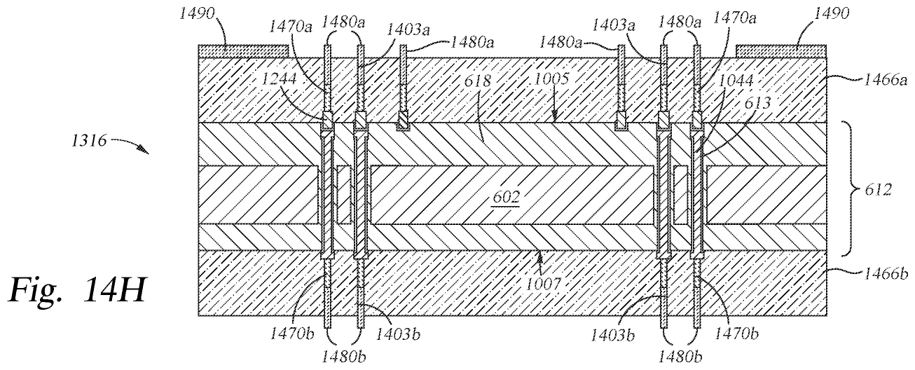

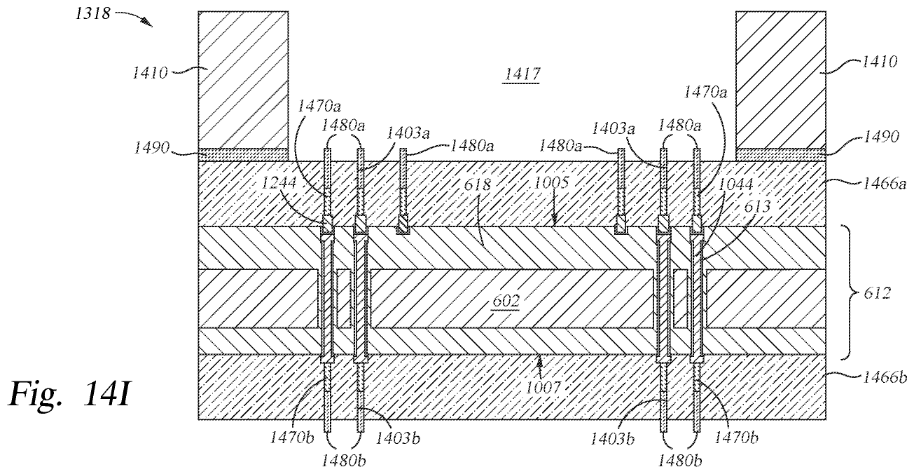

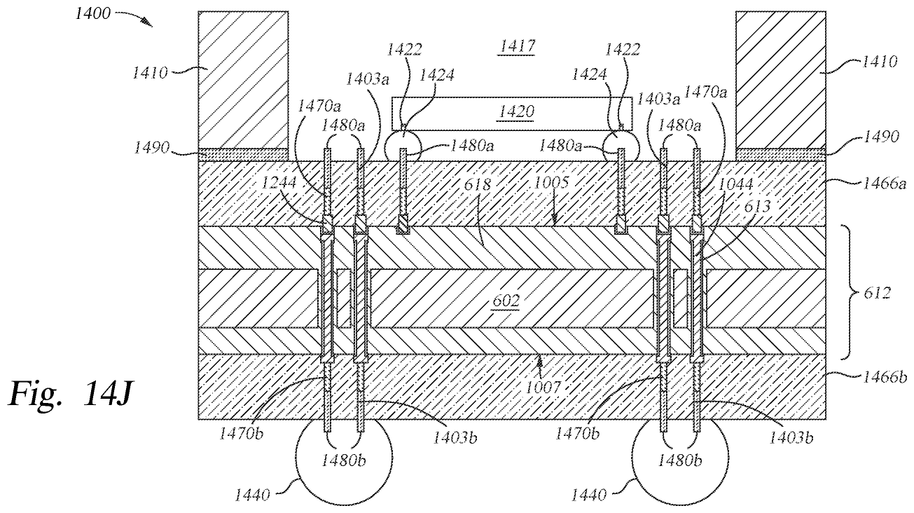

In general, the method 200 includes structuring a first substrate to be utilized as a core substrate, e.g., core substrate 102, and a second substrate to be utilized as a stiffener frame, e.g., stiffener frame 110, at operation 210, further described in greater detail with reference to FIGS. 3 and 4A-4D. At operation 220, an insulating layer is formed on the core substrate, further described in greater detail with reference to FIGS. 5, 6A-6I, 7, and 8A-8E. At operation 230, one or more interconnections are formed through the core substrate and the insulating layer, further described in greater detail with reference to FIGS. 9 and 10A-10H. At operation 240, one or more redistribution layers are formed on the insulating layer to relocate contact points of the interconnections to desired locations on a surface of an assembled core assembly, further described in greater detail with reference to FIGS. 11 and 12A-12L. At operation 250, the stiffener frame is attached to the assembled core assembly, further described in greater detail with reference to FIGS. 13 and 14A-14J.

FIG. 3 illustrates a flow diagram of a representative method 300 for structuring a substrate 400, according to certain embodiments of the present disclosure. The method 300 may be utilized to pattern both of the core substrate and the stiffener frame as described above with reference to operation 210 of method 200. FIGS. 4A-4D schematically illustrate cross-sectional views of a substrate 400 at various stages of the substrate structuring process 300 represented in FIG. 3, according to certain embodiments of the present disclosure. For clarity, FIG. 3 and FIGS. 4A-4D are herein described together for clarity.

The method 300 begins at operation 310 and corresponding FIG. 4A. As described with reference to the core substrate 102 and/or stiffener frame 110 above, the substrate 400 is formed of any suitable substrate material including but not limited to a III-V compound semiconductor material, silicon, crystalline silicon (e.g., Si<100> or Si<111>), silicon oxide, silicon germanium, doped or undoped silicon, undoped high resistivity silicon, doped or undoped polysilicon, silicon nitride, silicon carbide, quartz, glass material (e.g., borosilicate glass), sapphire, alumina, and/or ceramic material. In certain embodiments, the substrate 400 is a monocrystalline p-type or n-type silicon substrate. In certain embodiments, the substrate 400 is a multicrystalline p-type or n-type silicon substrate. In another embodiment, the substrate 400 is a p-type or an n-type silicon solar substrate.

The substrate 400 may further have a polygonal or circular shape. For example, the substrate 400 may include a substantially square silicon substrate having lateral dimensions between about 120 mm and about 180 mm, with or without chamfered edges. In another example, the substrate 400 may include a circular silicon containing wafer having a diameter between about 20 mm and about 700 mm, such as between about 100 mm and about 500 mm, for example about 200 mm or about 300 mm. Unless otherwise noted, embodiments and examples described herein are conducted on substrates having a thickness between about 50 μm and about 1500 μm, such as a thickness between about 90 μm and about 780 μm. For example, the substrate 400 has a thickness between about 100 μm and about 300 μm, such as a thickness between about 110 μm and about 200 μm, such as a thickness of about 140 μm.

Prior to operation 310, the substrate 400 may be sliced and separated from a bulk material by wire sawing, scribing and breaking, mechanical abrasive sawing, or laser cutting. Slicing typically causes mechanical defects or deformities in substrate surfaces formed therefrom, such as scratches, micro-cracking, chipping, and other mechanical defects. Thus, the substrate 400 is exposed to a first damage removal process at operation 310 to smoothen and planarize surfaces thereof and remove mechanical defects in preparation for later structuring operations. In some embodiments, the substrate 400 may further be thinned by adjusting the process parameters of the first damage process. For example, a thickness of the substrate 400 may be decreased with increased exposure to the first damage removal process.

The first damage removal process at operation 310 includes exposing the substrate 400 to a substrate polishing process and/or an etch process followed by rinsing and drying processes. In some embodiments, operation 310 includes a chemical mechanical polishing (CMP) process. In certain embodiments, the etch process is a wet etch process including a buffered etch process that is selective for the removal of a desired material (e.g., contaminants and other undesirable compounds). In other embodiments, the etch process is a wet etch process utilizing an isotropic aqueous etch process. Any suitable wet etchant or combination of wet etchants may be used for the wet etch process. In certain embodiments, the substrate 400 is immersed in an aqueous HF etching solution for etching. In another embodiment, the substrate 400 is immersed in an aqueous KOH etching solution for etching.

In some embodiments, the etching solution is heated to a temperature between about 30° C. and about 100° C. during the etch process, such as between about 40° C. and 90° C. For example, the etching solution is heated to a temperature of about 70° C. In still other embodiments, the etch process at operation 310 is a dry etch process. An example of a dry etch process includes a plasma-based dry etch process. The thickness of the substrate 400 is modulated by controlling the time of exposure of the substrate 400 to the etchants (e.g., etching solution) utilized during the etch process. For example, a final thickness of the substrate 400 is reduced with increased exposure to the etchants. Alternatively, the substrate 400 may have a greater final thickness with decreased exposure to the etchants.

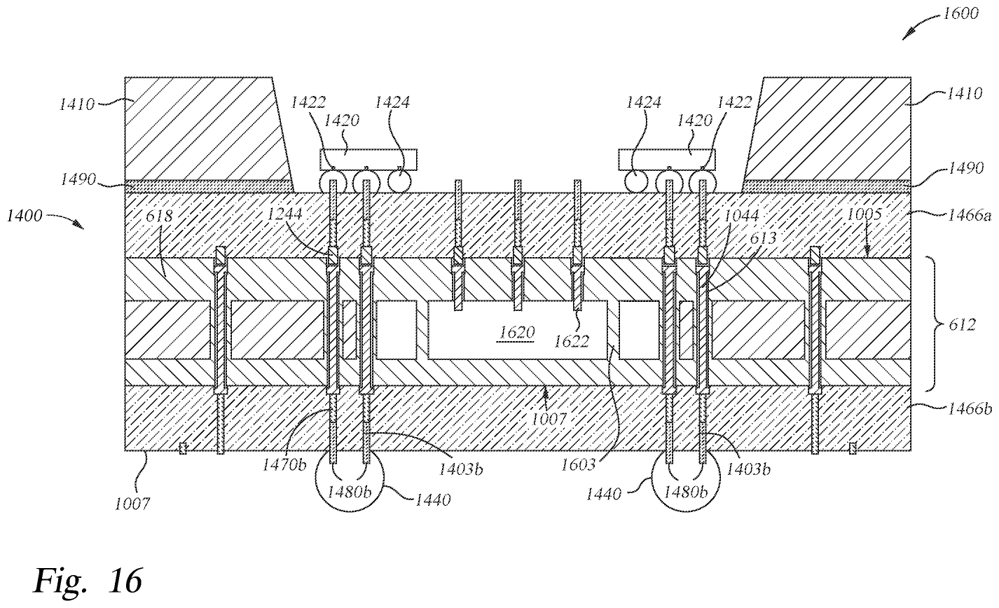

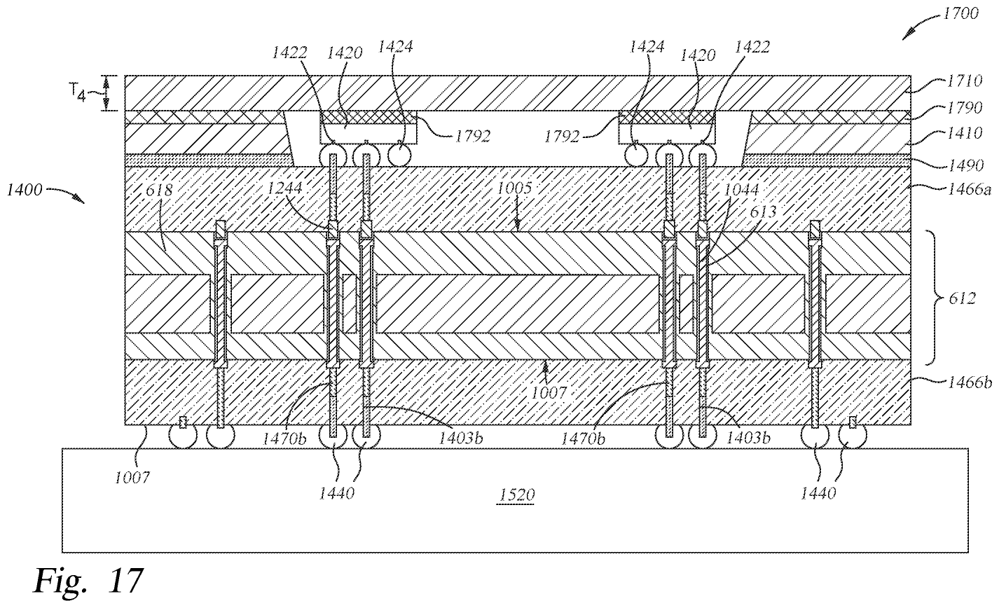

At operation 320, the now planarized and substantially defect-free substrate 400 is patterned to form one or more features 403 therein, such as vias for routing of interconnections through a core substrate, and/or cavities for embedding semiconductor dies or other devices within the core substrate (described in further detail with reference to FIG. 16), or openings for placement of one or more semiconductor dies or other devices within a stiffener frame. Four vias 403 are depicted in the cross-section of substrate 400 in FIG. 4B purposes of illustration and not limitation.

Generally, the features 403 may be formed by laser ablation (e.g. direct laser patterning). Any suitable laser ablation system may be utilized to form the features 403. In some examples, the laser ablation system utilizes an infrared (IR) laser source. In some examples, the laser source is a picosecond ultraviolet (UV) laser. In other examples, the laser is a femtosecond UV laser. In still other examples, the laser source is a femtosecond green laser. The laser source of the laser ablation system generates a continuous or pulsed laser beam for patterning of the substrate 400. For example, the laser source may generate a pulsed laser beam having a frequency between 5 kHz and 500 kHz, such as between 10 kHz and about 200 kHz. In one example, the laser source is configured to deliver a pulsed laser beam at a wavelength between about 200 nm and about 1200 nm and a pulse duration between about 10 ns and about 5000 ns with an output power between about 10 Watts and about 100 Watts. The laser source is configured to form any desired pattern of features in the substrate 400, including the vias, cavities, and openings described above.

In some embodiments, the substrate 400 is optionally coupled to a carrier plate (not shown) before being patterned. The optional carrier plate may provide mechanical support for the substrate 400 during patterning thereof and may prevent the substrate 400 from breaking. The carrier plate may be formed of any suitable chemically- and thermally-stable rigid material including but not limited to glass, ceramic, metal, or the like. In some examples, the carrier plate has a thickness between about 1 mm and about 10 mm, such as between about 2 mm and about 5 mm. In certain embodiments, the carrier plate has a textured surface. In other embodiments, the carrier plate has a polished or smoothened surface. The substrate 400 may be coupled to the carrier plate utilizing any suitable temporary bonding material, including but not limited to wax, glue, or similar bonding material.

In some embodiments, patterning the substrate 400 may cause unwanted mechanical defects in the surfaces of the substrate 400, including chipping, cracking, and/or warping. Thus, after performing operation 320 to form the features 403 in the substrate 400, the substrate 400 is exposed to a second damage removal and cleaning process at operation 330 substantially similar to the first damage removal process at operation 310 to smoothen the surfaces of the substrate 400 and remove unwanted debris. As described above, the second damage removal process includes exposing the substrate 400 to a wet or dry etch process, followed by rinsing and drying thereof. The etch process proceeds for a predetermined duration to smoothen the surfaces of the substrate 400, and particularly the surfaces exposed to laser patterning operations. In another aspect, the etch process is utilized to remove any undesired debris remaining on the substrate 400 from the patterning process.

After removal of mechanical defects in the substrate 400 at operation 330, the substrate 400 is exposed to an optional passivation or metallization process at operation 340 and FIG. 4D to grow or deposit a passivating layer, such as oxide layer 404, or a metal layer, such as metal cladding layer 414 or metal shielding layer 412, on desired surfaces thereof (e.g., all surfaces of the substrate 400). In certain embodiments, the passivation process is a thermal oxidation process. The thermal oxidation process is performed at a temperature between about 800° C. and about 1200° C., such as between about 850° C. and about 1150° C. For example, the thermal oxidation process is performed at a temperature between about 900° C. and about 1100° C., such as a temperature between about 950° C. and about 1050° C. In certain embodiments, the thermal oxidation process is a wet oxidation process utilizing water vapor as an oxidant. In certain embodiments, the thermal oxidation process is a dry oxidation process utilizing molecular oxygen as the oxidant. It is contemplated that the substrate 400 may be exposed to any suitable passivation process at operation 340 to form the oxide layer 404 or any other suitable passivating layer thereon. The resulting oxide layer 404 generally has a thickness between about 100 nm and about 3 μm, such as between about 200 nm and about 2.5 μm. For example, the oxide layer 404 has a thickness between about 300 nm and about 2 μm, such as about 1.5 μm.

Alternatively, the metallization process may be any suitable metal deposition process, including an electroless deposition process, an electroplating process, a chemical vapor deposition process, an evaporation deposition process, and/or an atomic layer deposition process. In examples where a metal cladding layer 414 is formed, at least a portion of the metal cladding layer 414 includes a deposited nickel (Ni) layer formed by direct displacement or displacement plating on the surfaces of the substrate 400 (e.g., n-Si substrate or p-Si substrate). For example, the substrate 400 is exposed to a nickel displacement plating bath having a composition including 0.5 M NiSO₄ and NH₄OH at a temperature between about 60° C. and about 95° C. and a pH of about 11, for a period of between about 2 and about 4 minutes. The exposure of the silicon substrate 400 to a nickel ion-loaded aqueous electrolyte in the absence of reducing agent causes a localized oxidation/reduction reaction at the surface of the substrate 400, thus leading to plating of metallic nickel thereon. Accordingly, nickel displacement plating enables selective formation of thin and pure nickel layers on the silicon material of substrate 400 utilizing stable solutions. Furthermore, the process is self-limiting and thus, once all surfaces of the substrate 400 are plated (e.g., there is no remaining silicon upon which nickel can form), the reaction stops. In certain embodiments, the nickel metal cladding layer 414 may be utilized as a seed layer for plating of additional metal layers, such as for plating of nickel or copper by electroless and/or electrolytic plating methods. In further embodiments, the substrate 400 is exposed to an SC-1 pre-cleaning solution and a HF oxide etching solution prior to a nickel displacement plating bath to promote adhesion of the nickel metal cladding layer 414 thereto.

Upon passivation or metallization, the substrate 400 is ready to be utilized as a core substrate or stiffener frame for the formation of a core assembly, such as the semiconductor core assembly 100.

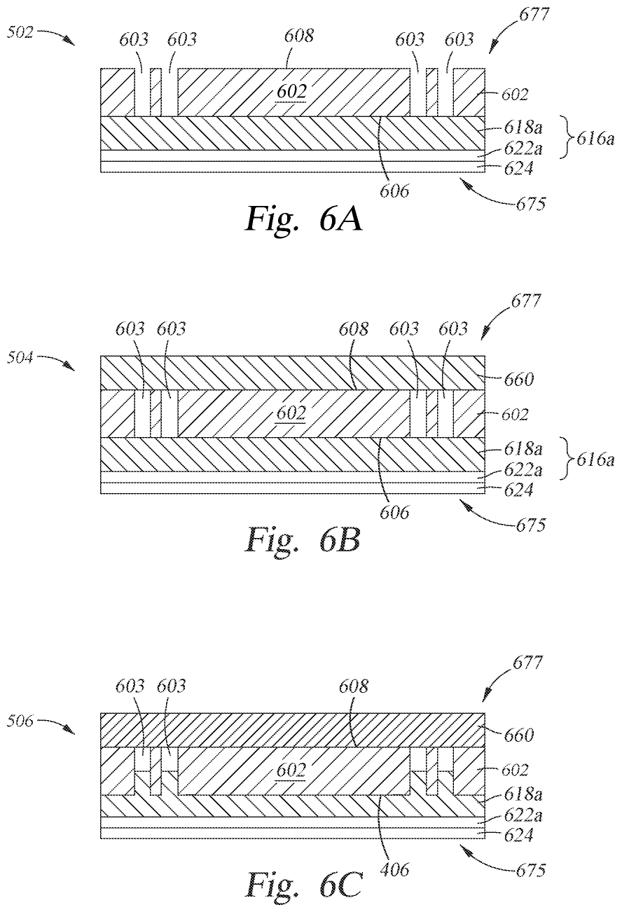

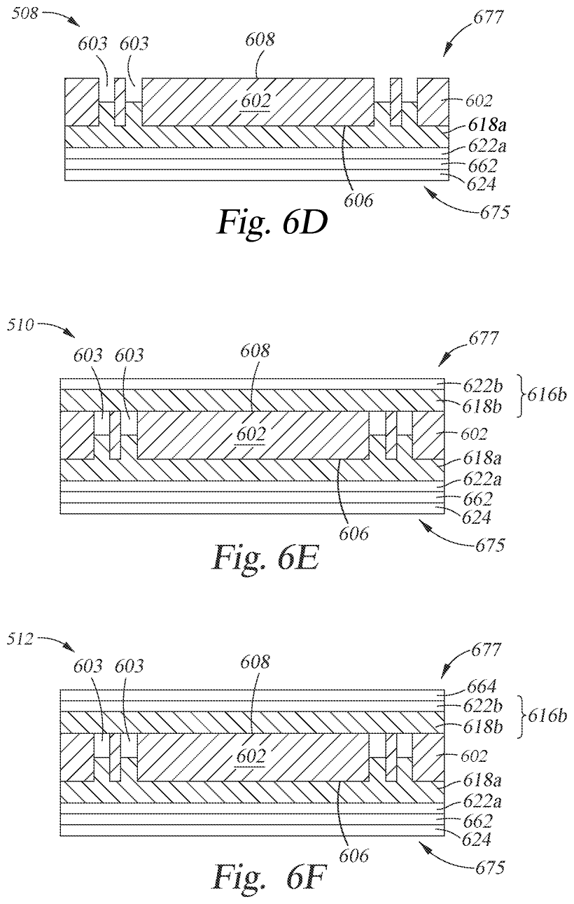

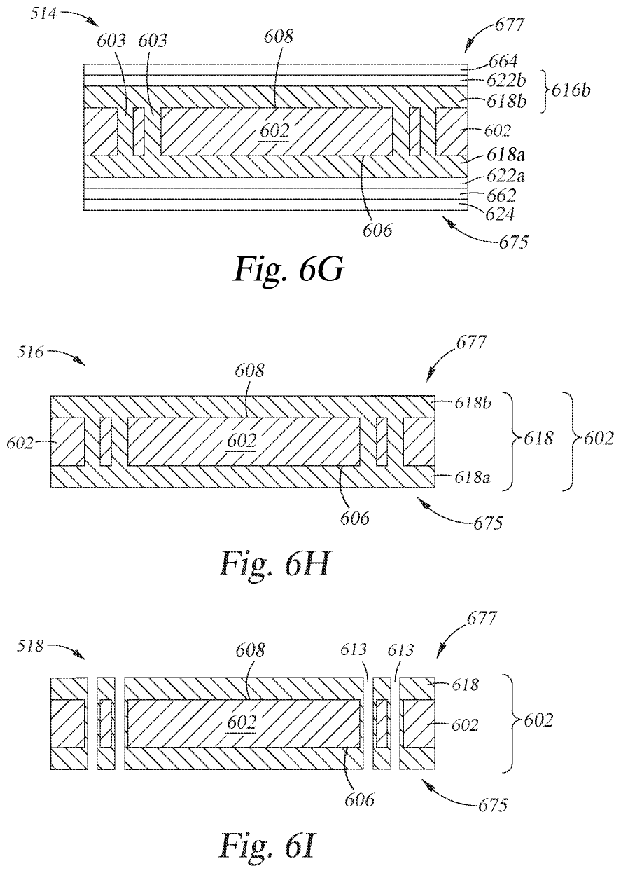

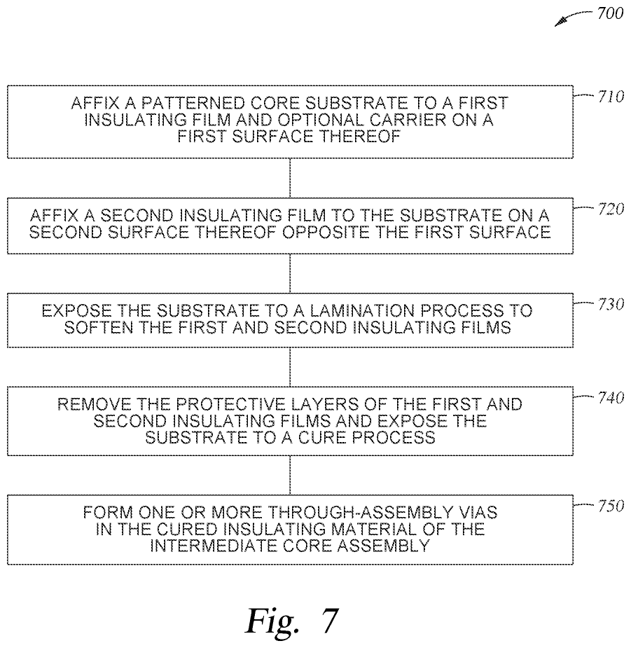

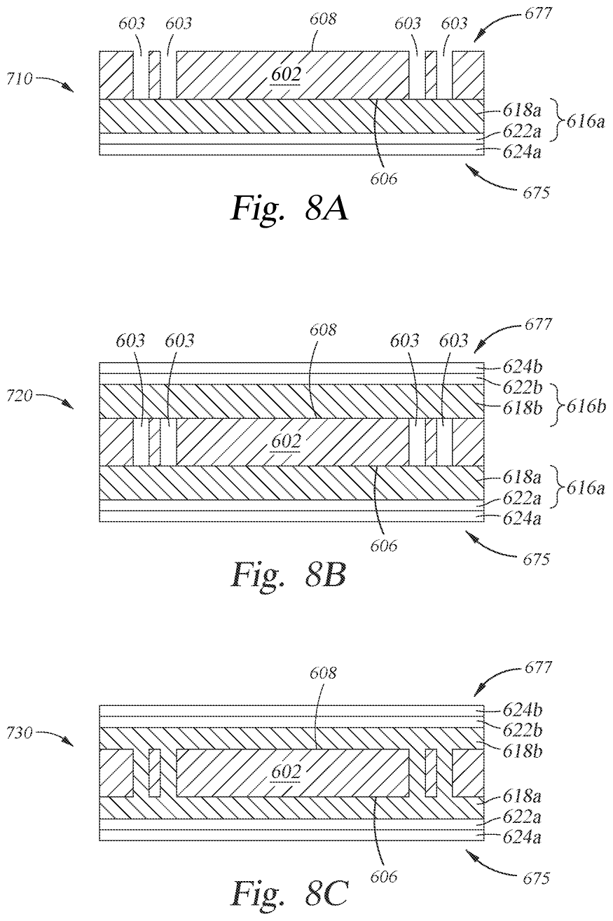

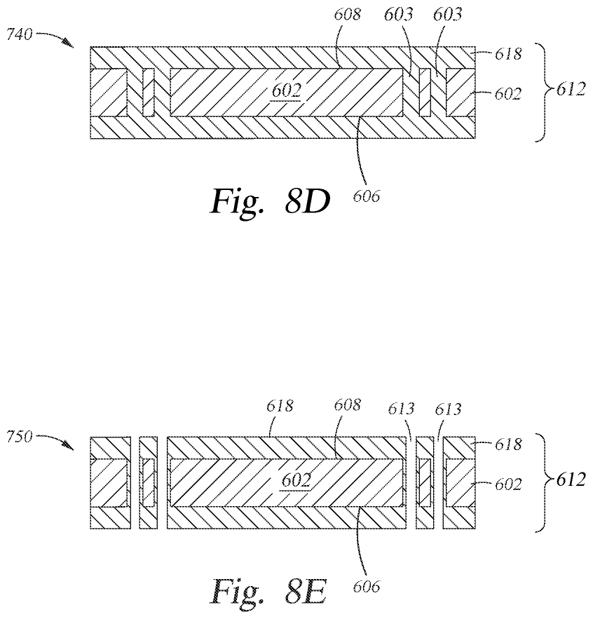

FIGS. 5 and 7 illustrate flow diagrams of representative methods 500 and 700, respectively, for forming an insulating layer 618 on a core substrate 602, according to certain embodiments of the present disclosure. Core substrate 602 may have been previous structured via method 300 described above. FIGS. 6A-6I schematically illustrate cross-sectional views of the core substrate 602 at different stages of the method 500 depicted in FIG. 5, and FIGS. 8A-8E schematically illustrate cross-sectional views of the core substrate 602 at different stages of the method 700 depicted in FIG. 7, according to certain embodiments of the present disclosure. For clarity, FIG. 5 and FIGS. 6A-6I are herein described together, and similarly, FIG. 7 and FIGS. 8A-8E are herein described together.

Generally, the method 500 begins at operation 502 and FIG. 6A wherein a first surface 606 of the core substrate 602 at a first side 675, now having vias 603 formed therein and the oxide layer 604 formed thereon, is placed on and affixed to a first insulating film 616a. In certain embodiments, the first insulating film 616a includes one or more layers formed of polymer-based dielectric materials. For example, the first insulating film 616a includes one or more layers formed of flowable build-up materials. In certain embodiments, the first insulating film 616a includes a flowable epoxy resin layer 618a. Generally, the epoxy resin layer 618a has a thickness less than about 60 μm, such as between about 5 μm and about 50 μm. For example, the epoxy resin layer 618a has a thickness between about 10 μm and about 25 μm.

The epoxy resin layer 618a may be formed of a ceramic-filler-containing epoxy resin, such as an epoxy resin filled with (e.g., containing) silica (SiO₂) particles. Other examples of ceramic fillers that may be used to form the epoxy resin layer 618a and other layers of the insulating film 616a include aluminum nitride (AlN), aluminum oxide (Al₂O₃), silicon carbide (SiC), silicon nitride (Si₃N₄), Sr₂Ce₂Ti₅O₁₆, zirconium silicate (ZrSiO₄), wollastonite (CaSiO₃), beryllium oxide (BeO), cerium dioxide (CeO₂), boron nitride (BN), calcium copper titanium oxide (CaCu₃Ti₄O₁₂), magnesium oxide (MgO), titanium dioxide (TiO₂), zinc oxide (ZnO) and the like. In some examples, the ceramic fillers utilized to form the epoxy resin layer 618a have particles ranging in size between about 40 nm and about 1.5 μm, such as between about 80 nm and about 1 μm. For example, the ceramic fillers utilized to form the epoxy resin layer 618a have particles ranging in size between about 200 nm and about 800 nm, such as between about 300 nm and about 600 nm.

In some embodiments, the first insulating film 616a further includes one or more protective layers. For example, the first insulating film 616a includes a polyethylene terephthalate (PET) protective layer 622a, such as a biaxial PET protective layer 622a. However, any suitable number and combination of layers and materials is contemplated for the first insulating film 616a. In some embodiments, the entire insulating film 616a has a thickness less than about 120 μm, such as a thickness less than about 90 μm.

In some embodiments, after affixing the core substrate 602 to the first insulating film 616a, the core substrate 602 may then be placed on a carrier 624 adjacent the first side 675 thereof for additional mechanical stabilization during later processing operations. Generally, the carrier 624 is formed of any suitable mechanically and thermally stable material capable of withstanding temperatures above 100° C. For example, in certain embodiments, the carrier 624 comprises polytetrafluoroethylene (PTFE). In another example, the carrier 624 is formed of polyethylene terephthalate (PET).

At operation 504 and FIG. 6B, a first protective film 660 is affixed to a second surface 608 on a second side 677 of the core substrate 602. The protective film 660 is coupled to the core substrate 602 on the second side 677 and opposite of the first insulating film 616a such that it covers the vias 603. In certain embodiments, the protective film 660 is formed of a material similar to that of the protective layer 622a. For example, the protective film 660 is formed of PET, such as biaxial PET. However, the protective film 660 may be formed of any suitable protective materials. In some embodiments, the protective film 660 has a thickness between about 50 μm and about 150 μm.

The core substrate 602, now affixed to the insulating film 616a at the first side 675 and the protective film 660 at the second side 677, is exposed to a first lamination process at operation 506. During the lamination process, the core substrate 602 is exposed to elevated temperatures, causing the epoxy resin layer 618a of the insulating film 616a to soften and flow into the open voids or volumes between the insulating film 616a and the protective film 660, such as into the vias 603. Accordingly, the vias 603 become at least partially filled (e.g., occupied) with the insulating material of the epoxy resin layer 618a, as depicted in FIG. 6C. Further, the core substrate 602 becomes partially surrounded by the insulating material of the epoxy resin layer 618a.

In embodiments where core substrate 602 has cavities formed therein (shown in FIG. 16), semiconductor dies may be placed within the cavities prior to operation 506. Then, at operation 506, upon lamination of the epoxy resin layer 618a, the cavities also become partially filled with epoxy resin layer 618a, thus partially embedding the semiconductor dies within the cavities.

In certain embodiments, the lamination process is a vacuum lamination process that may be performed in an autoclave or other suitable device. In certain embodiments, the lamination process is performed by use of a hot pressing process. In certain embodiments, the lamination process is performed at a temperature between about 80° C. and about 140° C. and for a period between about 1 minute and about 30 minutes. In some embodiments, the lamination process includes the application of a pressure between about 1 psig and about 150 psig while a temperature between about 80° C. and about 140° C. is applied to core substrate 602 and insulating film 616a for a period between about 1 minute and about 30 minutes. For example, the lamination process is performed by applying a pressure between about 10 psig and about 100 psig, and a temperature between about 100° C. and about 120° C. for a period between about 2 minutes and 10 minutes. For example, the lamination process is performed at a temperature of about 110° C. for a period of about 5 minutes.

At operation 508, the protective film 660 is removed and the core substrate 602, now having the laminated insulating material of the epoxy resin layer 618a at least partially surrounding the core substrate 602 and partially filling the vias 603, is placed on a second protective film 662. As depicted in FIG. 6D, the second protective film 662 is coupled to the core substrate 602 adjacent the first side 675 such that the second protective film 662 is disposed against (e.g., adjacent) the protective layer 622a of the insulating film 616a. In some embodiments, the core substrate 602, now coupled to the protective film 662, may be optionally placed on the carrier 624 for additional mechanical support on the first side 675. In some embodiments, the protective film 662 is placed on the carrier 624 prior to coupling the protective film 662 with the core substrate 602. Generally, the protective film 662 is substantially similar in composition to the protective film 660. For example, the protective film 662 may be formed of PET, such as biaxial PET. However, the protective film 662 may be formed of any suitable protective materials. In some embodiments, the protective film 662 has a thickness between about 50 μm and about 150 μm.

Upon coupling the core substrate 602 to the second protective film 662, a second insulating film 616b substantially similar to the first insulating film 616a is placed over the second side 677 at operation 510 and FIG. 6E, thus replacing the protective film 660. In certain embodiments, the second insulating film 616b is positioned on the second side 677 of the core substrate 602 such that an epoxy resin layer 618b of the second insulating film 616b covers the vias 603. In certain embodiments, the placement of the second insulating film 616b on the core substrate 602 may form one or more voids between the insulating film 616b and the already-laminated insulating material of the epoxy resin layer 618a that partially surrounds the core substrate 602 and partially fills the vias 603. The second insulating film 616b may include one or more layers formed of polymer-based dielectric materials similar to the insulating film 616a. As depicted in FIG. 6E, the second insulating film 616b includes an epoxy resin layer 618b substantially similar to the epoxy resin layer 618a described above. The second insulating film 616b may further include a protective layer 622b formed of similar materials to the protective layer 622a, such as PET.

At operation 512, a third protective film 664 is placed over the second insulating film 616b, as depicted in FIG. 6F. Generally, the protective film 664 is substantially similar in composition to the protective films 660, 662. For example, the protective film 664 is formed of PET, such as biaxial PET. However, the protective film 664 may be formed of any suitable protective materials. In some embodiments, the protective film 664 has a thickness between about 50 μm and about 150 μm.

The core substrate 602, now affixed to the insulating film 616b and the protective film 664 on the second side 677 and the protective film 662 and the optional carrier 624 on the first side 675, is exposed to a second lamination process at operation 514 and FIG. 6G. Similar to the lamination process at operation 504, the core substrate 602 is exposed to elevated temperatures, causing the epoxy resin layer 618b of the insulating film 616b to soften and flow into any open voids or volumes between the insulating film 616b and the already-laminated insulating material of the epoxy resin layer 618a, thus integrating itself with the insulating material of the epoxy resin layer 618a. Accordingly, the vias 603 become completely filled (e.g. packed, sealed) with insulating material of both epoxy resin layers 618a, 618b.

In embodiments where core substrate 602 has cavities formed therein (shown in FIG. 16), semiconductor dies may be placed within the cavities prior to operation 506. Then, upon lamination of the epoxy resin layer 618a at operations 506 and 514, the cavities become filled with epoxy resin layer 618a, thus embedding the semiconductor dies within the cavities.

In certain embodiments, the second lamination process is a vacuum lamination process that may be performed in an autoclave or other suitable device. In certain embodiments, the lamination process is performed by use of a hot pressing process. In certain embodiments, the lamination process is performed at a temperature between about 80° C. and about 140° C. and for a period between about 1 minute and about 30 minutes. In some embodiments, the lamination process includes the application of a pressure between about 1 psig and about 150 psig while a temperature between about 80° C. and about 140° C. is applied to the core substrate 602 and the insulating film 616a for a period between about 1 minute and about 30 minutes. For example, the lamination process is performed by applying a pressure between about 10 psig and about 100 psig, and a temperature between about 100° C. and about 120° C. for a period between about 2 minutes and 10 minutes. For example, the lamination process is performed at a temperature of about 110° C. for a period of about 5 minutes.

After lamination, the core substrate 602 is disengaged from the carrier 624 at operation 516 and the protective films 662, 664 are removed, resulting in a laminated intermediate core assembly 612. As depicted in FIG. 6H, the intermediate core assembly 612 includes the core substrate 602 having one or more vias 603 formed therethrough and filled with the insulating dielectric material of the insulating films 616a, 616b. The insulating dielectric material of the epoxy resin layers 618a, 618b may further encases the core substrate 602 (which may have the oxide layer or metal layer formed thereon) such that the insulating material covers at least two surfaces or sides of the core substrate 602 (e.g., surfaces 606, 608). In some examples, the protective layers 622a, 622b are also removed from the intermediate core assembly 612 at operation 516. Generally, the protective layers 622a and 622b, the carrier 624, and the protective films 662 and 664 are removed from the intermediate core assembly 612 by any suitable mechanical processes such as peeling therefrom.

Upon removal of the protective layers 622a, 622b and the protective films 662, 664, the intermediate core assembly 612 is exposed to a cure process to fully cure (i.e., harden through chemical reactions and cross-linking) the insulating dielectric material of the epoxy resin layers 618a, 618b, thus forming an insulating layer 618. As shown, the insulating layer 618 substantially surrounds the core substrate 602 and fills the vias 603. For example, the insulating layer 618 contacts or encapsulates at least the major, lateral surfaces of the core substrate 602 (such as surfaces 606, 608).

In certain embodiments, the cure process is performed at high temperatures to fully cure the intermediate core assembly 612. For example, the cure process is performed at a temperature between about 140° C. and about 220° C. and for a period between about 15 minutes and about 45 minutes, such as a temperature between about 160° C. and about 200° C. and for a period between about 25 minutes and about 35 minutes. For example, the cure process is performed at a temperature of about 180° C. for a period of about 30 minutes. In further embodiments, the cure process at operation 516 is performed at or near ambient (e.g., atmospheric) pressure conditions.

After curing, one or more through-assembly vias 613 are drilled through the intermediate core assembly 612 at operation 518, forming channels through the entire thickness of the intermediate core assembly 612 for subsequent interconnection formation. In some embodiments, the intermediate core assembly 612 may be placed on a carrier, such as the carrier 624, for mechanical support during the formation of the through-assembly vias 613. The through-assembly vias 613 are drilled through the vias 603 that were formed in the core substrate 602 and were subsequently filled with the insulating layer 618. Thus, the through-assembly vias 613 may be circumferentially surrounded by the insulating layer 618 filled within the vias 603.

By having the ceramic-filler-containing epoxy resin material of the insulating layer 618 line the walls of the vias 603, capacitive coupling between the conductive silicon-based core substrate 602 and subsequently-formed interconnections 1044 (described with reference to FIG. 9 and FIGS. 10A-10H) in the singulated semiconductor core assembly 1270 (described with reference to FIGS. 10G and 11, as well as FIGS. 12K and 12L) is significantly reduced as compared to other conventional interconnecting structures that utilize conventional via-insulating liners or films. Furthermore, the flowable nature of the epoxy resin material of the insulating layer 618 enables more consistent and reliable encapsulation and insulation, thus enhancing electrical performance by minimizing leakage current of the completed semiconductor core assembly 1270.

In certain embodiments, the through-assembly vias 613 have a diameter less than about 100 μm, such as less than about 75 μm. For example, the through-assembly vias 613 have a diameter less than about 50 μm, such as less than about 35 μm. In some embodiments, the through-assembly vias 613 have a diameter between about 25 μm and about 50 μm, such as a diameter between about 35 μm and about 40 μm. In certain embodiments, the through assembly vias 613 are formed using any suitable mechanical process. For example, the through-assembly vias 613 are formed using a mechanical drilling process. In certain embodiments, through-assembly vias 613 are formed through the intermediate core assembly 612 by laser ablation. For example, the through-assembly vias 613 are formed using an ultraviolet laser. In certain embodiments, the laser source utilized for laser ablation has a frequency between about 5 kHz and about 500 kHz. In certain embodiments, the laser source is configured to deliver a pulsed laser beam at a pulse duration between about 10 ns and about 100 ns with a pulse energy between about 50 microjoules (μJ) and about 500 μJ. Utilizing an epoxy resin material containing small ceramic filler particles further promotes more precise and accurate laser patterning of small-diameter vias, such as the through-assembly vias 613, as the small ceramic filler particles therein exhibit reduced laser light reflection, scattering, diffraction, and transmission of the laser light away from the area in which the via is to be formed during the laser ablation process.

In some embodiments, the through-assembly vias 613 are formed within (e.g., through) the vias 603 in such a way that the remaining ceramic-filler-containing epoxy resin material (e.g., dielectric insulating material) on the sidewalls of the vias 603 has an average thickness between about 1 μm and about 50 μm. For example, the remaining ceramic-filler-containing epoxy resin material on the sidewalls of the vias 603 has an average thickness between about 5 μm and about 40 μm, such as between about 10 μm and about 30 μm. Accordingly, the resulting structure after formation of the through-assembly vias 613 may be described as a “via-in-via” (e.g., a via centrally formed in a dielectric material within a via of the core structure). In certain embodiments, the via-in-via structure includes a dielectric sidewall passivation consisting of a ceramic-particle-filled epoxy material and disposed on a thin layer of thermal oxide formed on the sidewalls of the vias 603.

In embodiments where a metal cladding layer 114, 414 is formed over the core substrate 602, one or more cladding vias 123 may also be formed at operation 518 to provide channels for cladding connections 116 (shown in FIG. 1B). As described above, the cladding vias 123 are formed in the insulating layer 118 above and/or below the core substrate 102 to enable coupling of the metal cladding layer 114, 414 to cladding connections 116 so that the metal cladding layer 114, 414 can be connected to an external common ground or reference voltage. In certain embodiments, the cladding vias 123 have a diameter less than about 100 μm, such as less than about 75 μm. For example, the cladding vias 123 have a diameter less than about 50 μm, such as less than about 35 μm. In some embodiments, the cladding vias 123 have a diameter between about 5 μm and about 25 μm, such as a diameter between about 10 μm and about 20 μm.

In embodiments where intermediate core assembly 612 has semiconductor dies embedded therein (shown in FIG. 16), one or more additional through-assembly vias 613 may be formed in insulating layer 618 that expose one or more contacts of the semiconductor die for subsequent interconnection. The additional through-assembly vias 613 may be subsequently metallized, as described in further detail below.

After formation of the through-assembly vias 613 and/or cladding vias 123 (shown in FIG. 1B), the intermediate core assembly 612 is exposed to a de-smear process. During the de-smear process, any unwanted residues and/or debris caused by laser ablation during the formation of the through-assembly vias 613 and/or cladding vias 123 are removed from the intermediate core assembly 612. The de-smear process thus cleans the vias for subsequent metallization. In certain embodiments, the de-smear process is a wet de-smear process. Any suitable solvents, etchants, and/or combinations thereof may be utilized for the wet de-smear process. In one example, methanol may be utilized as a solvent and copper (II) chloride dihydrate (CuCl₂.H₂O) as an etchant. Depending on the residue thickness, exposure duration of the intermediate core assembly 612 to the wet de-smear process may be varied. In another embodiment, the de-smear process is a dry de-smear process. For example, the de-smear process may be a plasma de-smear process with an O₂/CF₄ mixture gas. The plasma de-smear process may include generating a plasma by applying a power of about 700 W and flowing O₂:CF₄ at a ratio of about 10:1 (e.g., 100:10 sccm) for a time period between about 60 seconds and about 120 seconds. In further embodiments, the de-smear process is a combination of wet and dry processes.

Following the de-smear process at operation 518, the intermediate core assembly 612 is ready for formation of interconnection paths therein (e.g., metallization), described below with reference to FIG. 9 and FIGS. 10A-10H.

As discussed above, FIG. 5 and FIGS. 6A-6I illustrate a representative method 500 for forming the intermediate core assembly 612. FIG. 7 and FIGS. 8A-8E illustrate an alternative method 700 substantially similar to the method 500, but with fewer operations, according to certain embodiments of the present disclosure. The method 700 generally includes five operations 710-750. However, operations 710, 740, and 750 of the method 700 are substantially similar to the operations 502, 516, and 518 of the method 500, respectively. Thus, only operations 720, 730, and 740, depicted in FIGS. 8B, 8C, and 8D, respectively, are herein described for clarity/brevity.

After fixing the first insulating film 616a to the first surface 606 on the first side 675 of the core substrate 602, a second insulating film 616b is coupled to the second surface 608 on the opposing side 677 at operation 720 and FIG. 8B. In some embodiments, the second insulating film 616b is positioned on the surface 608 of the core substrate 602 such that the epoxy resin layer 618b of the second insulating film 616b covers all of the vias 603. As depicted in FIG. 8B, the vias 603 form one or more voids or gaps between the insulating films 616a and 616b. In some embodiments, a second carrier 625 is affixed to the protective layer 622b of the second insulating film 616b for additional mechanical support during later processing operations.

At operation 730 and FIG. 8C, the core substrate 602, now affixed to the insulating films 616a and 616b on opposing sides thereof, is exposed to a single lamination process. During the single lamination process, the core substrate 602 is exposed to elevated temperatures, causing the epoxy resin layers 618a and 618b of both insulating films 616a, 616b to soften and flow into the open voids or volumes created by the vias 603 between the insulating films 616a, 616b. Accordingly, the vias 603 become filled with the insulating material of the epoxy resin layers 618a and 618b.

In embodiments where core substrate 602 has cavities formed therein (shown in FIG. 16), semiconductor dies may be placed within the cavities prior to operation 730. Then, upon lamination of the epoxy resin layers 618a, 618b at operations 730, the cavities become filled with epoxy resin layers 618a, 618b, thus embedding the semiconductor dies within the cavities.

Similar to the lamination processes described with reference to FIG. 5 and FIGS. 6A-6I, the lamination process at operation 730 may be a vacuum lamination process that may be performed in an autoclave or other suitable device. In another embodiment, the lamination process is performed by use of a hot pressing process. In certain embodiments, the lamination process is performed at a temperature between about 80° C. and about 140° C. and for a period between about 1 minute and about 30 minutes. In some embodiments, the lamination process includes the application of a pressure between about 1 psig and about 150 psig while a temperature between about 80° C. and about 140° C. is applied to core substrate 602 and the insulating films 616a, 616b for a period between about 1 minute and about 30 minutes. For example, the lamination process is performed at a pressure between about 10 psig and about 100 psig, a temperature between about 100° C. and about 120° C., and for a period between about 2 minutes and 10 minutes. For example, the lamination process at operation 730 is performed at a temperature of about 110° C. for a period of about 5 minutes.

At operation 740, the one or more protective layers of the insulating films 616a, 616b are removed from the core substrate 602, resulting in the laminated intermediate core assembly 612. In one example, the protective layers 622a, 622b are removed from the core substrate 602, and thus the intermediate core assembly 612 is also disengaged from the first and second carriers 624, 625. Generally, the protective layers 622a, 622b and the carriers 624, 625 are removed by any suitable mechanical processes such as peeling therefrom. As depicted in FIG. 8D, the intermediate core assembly 612 includes the core substrate 602 having one or more vias 603 formed therein and filled with the insulating dielectric material of the epoxy resin layers 618a, 618b. The insulating material further encases the core substrate 602 such that the insulating material covers at least two surfaces or sides of the core substrate 602, for example, the surfaces 606, 608.

Upon removal of the protective layers 622a, 622b, the intermediate core assembly 612 is exposed to a cure process to fully cure the insulating dielectric material of the epoxy resin layers 618a, 618b. Curing of the insulating material results in the formation of the insulating layer 618. As depicted in FIG. 8D and similar to operation 516 corresponding with FIG. 6H, the insulating layer 618 substantially surrounds the core substrate 602 and fills the vias 603.

In certain embodiments, the cure process is performed at high temperatures to fully cure the intermediate core assembly 612. For example, the cure process is performed at a temperature between about 140° C. and about 220° C. and for a period between about 15 minutes and about 45 minutes, such as a temperature between about 160° C. and about 200° C. and for a period between about 25 minutes and about 35 minutes. For example, the cure process is performed at a temperature of about 180° C. for a period of about 30 minutes. In further embodiments, the cure process at operation 740 is performed at or near ambient (e.g. atmospheric) pressure conditions.

After curing at operation 740, the method 700 is substantially similar to operation 518 of the method 500. Accordingly, one or more through-assembly vias 613 and/or cladding vias 123 (shown in FIG. 1B) are drilled through the intermediate core assembly 612, followed by exposing the intermediate core assembly 612 to a de-smear process. Upon completion of the de-smear process, the intermediate core assembly 612 is ready for formation of interconnection paths therein, as described below.

FIG. 9 illustrates a flow diagram of a representative method 900 for forming electrical interconnections through the intermediate core assembly 612, according to certain embodiments of the present disclosure. FIGS. 10A-10H schematically illustrate cross-sectional views of the intermediate core assembly 612 at different stages of the process of the method 900 depicted in FIG. 9, according to certain embodiments of the present disclosure. For clarity, FIG. 9 and FIGS. 10A-10H are herein described together.

In certain embodiments, the electrical interconnections formed through the intermediate core assembly 612 are formed of copper. Thus, the method 900 generally begins at operation 910 and FIG. 10A wherein the intermediate core assembly 612, having through-assembly vias 613 formed therein, has a barrier or adhesion layer 1040 and/or a seed layer 1042 formed thereon. An enlarged partial view of the adhesion layer 1040 and the seed layer 1042 formed on the intermediate core assembly 612 is depicted in FIG. 10H for reference. The adhesion layer 1040 may be formed on desired surfaces of the insulating layer 618, such as surfaces corresponding with the major surfaces 1005, 1007 of the intermediate core assembly 612 as well as sidewalls of the through-assembly vias 613 and/or cladding vias 123, to assist in promoting adhesion and blocking diffusion of the subsequently formed seed layer 1042, electrical interconnections 1044, and/or cladding connections 116 (shown in FIG. 1B). Thus, in certain embodiments, the adhesion layer 1040 acts as an adhesion layer; in another embodiment, the adhesion layer 1040 acts as a barrier layer. In both embodiments, however, the adhesion layer 1040 will be hereinafter described as an “adhesion layer.”

In certain embodiments, the adhesion layer 1040 is formed of titanium, titanium nitride, tantalum, tantalum nitride, manganese, manganese oxide, molybdenum, cobalt oxide, cobalt nitride, or any other suitable materials or combinations thereof. In certain embodiments, the adhesion layer 1040 has a thickness between about 10 nm and about 300 nm, such as between about 50 nm and about 150 nm. For example, the adhesion layer 1040 has a thickness between about 75 nm and about 125 nm, such as about 100 nm. The adhesion layer 1040 is formed by any suitable deposition process, including but not limited to chemical vapor deposition (CVD), physical vapor deposition (PVD), plasma enhanced CVD (PECVD), atomic layer deposition (ALD), or the like.

The seed layer 1042 may be formed on the adhesion layer 1040 or directly on the insulating layer 618 (e.g., without the formation of the adhesion layer 1040). In some embodiments, the seed layer 1042 is formed on all surfaces of the insulating layer 618 while the adhesion layer 1040 is only formed on desired surfaces or desired portions of surfaces of the insulating layer 618. For example, the adhesion layer 1040 may be formed on the major surfaces 1005, 1007 and not on the sidewalls of the through-assembly vias 613 and/or cladding vias 123 (shown in FIG. 1B) while the seed layer 1042 is formed on the major surfaces 1005, 1007 as well as sidewalls of the vias. The seed layer 1042 is formed of a conductive material such as copper, tungsten, aluminum, silver, gold, or any other suitable materials or combinations thereof. In certain embodiments, the seed layer 1042 has a thickness between about 0.05 μm and about 0.5 μm, such as a thickness between about 0.1 μm and about 0.3 μm. For example, the seed layer 1042 has a thickness between about 0.15 μm and about 0.25 μm, such as about 0.2 μm. In certain embodiments, the seed layer 1042 has a thickness between about 0.1 μm and about 1.5 μm. Similar to the adhesion layer 1040, the seed layer 1042 is formed by any suitable deposition process, such as CVD, PVD, PECVD, ALD dry processes, wet electroless plating processes, or the like. In certain embodiments, a copper seed layer 1042 may be formed on a molybdenum adhesion layer 1040 on the intermediate core assembly 612. The molybdenum adhesion and copper seed layer combination enables improved adhesion with the surfaces of the insulating layer 618 and reduces undercut of conductive interconnect lines during a subsequent seed layer etch process at operation 970.

At operations 920 and 930, corresponding to FIGS. 10B and 10C, respectively, a spin-on/spray-on or dry resist film 1050, such as a photoresist, is applied to both major surfaces 1005, 1007 of the intermediate core assembly 612 and subsequently patterned. In certain embodiments, the resist film 1050 is patterned via selective exposure to UV radiation. In certain embodiments, an adhesion promoter (not shown) is applied to the intermediate core assembly 612 prior to formation of the resist film 1050. The adhesion promoter improves adhesion of the resist film 1050 to the intermediate core assembly 612 by producing an interfacial bonding layer for the resist film 1050 and by removing any moisture from the surface of the intermediate core assembly 612. In some embodiments, the adhesion promoter is formed of bis(trimethylsilyl)amine or hexamethyldisilizane (HMDS) and propylene glycol monomethyl ether acetate (PGMEA).

At operation 940, the intermediate core assembly 612 is exposed to a resist film development process. As depicted in FIG. 10D, development of the resist film 1050 results in exposure of the through-assembly vias 613 and/or cladding vias 123 (shown in FIG. 1B), which may now have an adhesion layer 1040 and/or a seed layer 1042 formed thereon. In certain embodiments, the film development process is a wet process, such as a wet process that includes exposing the resist film 1050 to a solvent. In certain embodiments, the film development process is a wet etch process utilizing an aqueous etch process. For example, the film development process is a wet etch process utilizing a buffered etch process selective for a desired material. Any suitable wet solvents or combination of wet etchants may be used for the resist film development process.

At operations 950 and 960, corresponding to FIGS. 10E and 10F respectively, electrical interconnections 1044 are formed through the exposed through-assembly vias 613 and the resist film 1050 is thereafter removed. In embodiments where the core substrate 102 has a metal cladding layer 114, 414 formed thereon, cladding connections 116 (shown in FIG. 1B) are also formed through exposed cladding vias 123 at operation 950. The interconnections 1044 and/or cladding connections 116 are formed by any suitable methods, including electroplating and electroless plating. In certain embodiments, the resist film 1050 is removed via a wet process. As depicted in FIGS. 10E and 10F, the electrical interconnections 1044 may completely fill the through-assembly vias 613 (the cladding connections 116 may also completely fill the cladding vias 123) and protrude from the surfaces 1005, 1007 of the intermediate core assembly 612 upon removal of the resist film 1050. In some embodiments, the electrical interconnections 1044 and/or the cladding connections 116 may only line the sidewalls of the vias without completely filling the vias. In certain embodiments, the electrical interconnections 1044 and/or cladding connections 116 are formed of copper. In other embodiments, the electrical interconnections 1044 and/or cladding connections 116 may be formed of any suitable conductive material including but not limited to aluminum, gold, nickel, silver, palladium, tin, or the like.

At operation 970 and FIG. 10G, the intermediate core assembly 612 having electrical interconnections 1044 and/or cladding connections 116 formed therein is exposed to a seed layer etch process to remove the exposed adhesion layer 1040 and seed layer 1042 on external surfaces thereof (e.g., surfaces 1005, 1007). In some embodiments, the adhesion layer 1040 and/or seed layer 1042 formed between the interconnections and the sidewalls of the vias may remain after the seed layer etch process. In certain embodiments, the seed layer etch is a wet etch process including a rinse and drying of the intermediate core assembly 612. In certain embodiments, the seed layer etch process is a buffered etch process selective for a desired material such as copper, tungsten, aluminum, silver, or gold. In other embodiments, the etch process is an aqueous etch process. Any suitable wet etchant or combination of wet etchants may be used for the seed layer etch process.

Note that in embodiments where intermediate core assembly 612 has semiconductor dies embedded therein (shown in FIG. 16), operations 910-970 may be performed to form conductive interconnections within one or more through-assembly vias leading to contacts on the semiconductor dies.

Following the seed layer etch process at operation 970, one or more semiconductor core assemblies may be singulated from the intermediate core assembly 612 and utilized as a fully-functional semiconductor core assembly 1270 (e.g., an electronic mounting or package structure). For example, the one or more semiconductor core assemblies may be singulated and utilized as circuit board structures, chip carrier structures, integrated circuit packages, and the like. Alternatively, the intermediate core assembly 612 may have one or more redistribution layers 1260 (shown in FIGS. 12J and 12K) formed thereon to reroute external contact points of the electrical interconnections 1044 to desired locations on the surfaces of the final semiconductor core assemblies.

FIG. 11 illustrates a flow diagram of a representative method 1100 of forming a redistribution layer 1260 on the intermediate core assembly 612, which has not yet been singulated into a semiconductor core assembly 1270, according to certain embodiments of the present disclosure. FIGS. 12A-12K schematically illustrate cross-sectional views of the intermediate core assembly 612 at different stages of the method 1100 depicted in FIG. 11, according to certain embodiments of the present disclosure. For clarity, FIG. 11 and FIGS. 12A-12K are herein described together for clarity.

The method 1100 is substantially similar to the methods 500, 700, and 900 described above. Generally, the method 1100 begins at operation 1102 and FIG. 12A, wherein an insulating film 1216 is affixed to the intermediate core assembly 612 and is thereafter laminated. The insulating film 1216 is substantially similar to the insulating films 616a, 616b. In certain embodiments, as depicted in FIG. 12A, the insulating film 1216 includes an epoxy resin layer 1218 and one or more protective layers. For example, the insulating film 1216 may include a protective layer 1222. Any suitable combination of layers and insulating materials is contemplated for the insulating film 1216. In some embodiments, an optional carrier 1224 is coupled to the insulating film 1216 for added support. In some embodiments, a protective film (not shown) may be coupled to the insulating film 1216.

Generally, the epoxy resin layer 1218 has a thickness of less than about 60 μm, such as between about 5 μm and about 50 μm. For example, the epoxy resin layer 1218 has a thickness of between about 10 μm and about 25 μm. In certain embodiments, the epoxy resin layer 1218 and the PET protective layer 1222 have a combined thickness of less than about 120 μm, such as a thickness of less than about 90 μm. The insulating film 1216, and specifically the epoxy resin layer 1218, is affixed to a surface of the intermediate core assembly 612 having exposed electrical interconnections 1044, such as the major surface 1005.

After placement of the insulating film 1216, the intermediate core assembly 612 is exposed to a lamination process substantially similar to the lamination process described with regard to operations 506, 514, and 730. The intermediate core assembly 612 is exposed to elevated temperatures to soften the epoxy resin layer 1218 of the insulating film 1216, which subsequently bonds to the insulating layer 618. Thus, the epoxy resin layer 1218 becomes integrated with the insulating layer 618 and forms an extension thereof, and will thus be described hereinafter as a singular insulating layer 618. The integration of the epoxy resin layer 1218 and the insulating layer 618 further results in an enlarged insulating layer 618 enveloping the previously exposed electrical interconnections 1044.

At operation 1104 and FIG. 12B, the protective layer 1222 and the carrier 1224 are removed from the intermediate core assembly 612 by mechanical means, and the intermediate core assembly 612 is exposed to a cure process to fully harden the newly expanded insulating layer 618. In certain embodiments, the cure process is substantially similar to the cure process described with reference to operations 516 and 740. For example, the cure process is performed at a temperature between about 140° C. and about 220° C. and for a period between about 15 minutes and about 45 minutes.

The intermediate core assembly 612 is then selectively patterned by laser ablation at operation 1106 and FIG. 12C. The laser ablation process at operation 1106 forms one or more redistribution vias 1253 in the newly expanded insulating layer 618 and exposes desired electrical interconnections 1044 for redistribution of contact points thereof. In certain embodiments, the redistribution vias 1253 have a diameter substantially similar to or smaller than the diameter of the through-assembly vias 613. For example, the redistribution vias 1253 have a diameter between about 5 μm and about 600 μm, such as a diameter of between about 10 μm and about 50 μm, such as between about 20 μm and about 30 μm. In certain embodiments, the laser ablation process at operation 1106 is performed utilizing a CO₂ laser. In certain embodiments, the laser ablation process at operation 1106 is performed utilizing a UV laser. In another embodiment, the laser ablation process at operation 1106 is performed utilizing a green laser. In one example, the laser source may generate a pulsed laser beam having a frequency between about 100 kHz and about 1000 kHz. In one example, the laser source is configured to deliver a pulsed laser beam at a wavelength of between about 100 nm and about 2000 nm, at a pulse duration between about 10E-4 ns and about 10E-2 ns, and with a pulse energy of between about 10 μJ and about 300 μJ.

In embodiments where the metal cladding layer 114, 414 is formed on the core substrate 102 (shown in FIG. 1B), the intermediate core assembly 612 may also be patterned at operation 1106 to form one or more cladding vias 123 through the extended insulating layer 618. Thus, for semiconductor core assemblies having one or more redistribution layers, the cladding vias 123 may be formed simultaneously with redistribution vias 1253 instead of forming the cladding vias 123 with the through-assembly vias 613 at operations 518 or 750. In certain other embodiments, however, the cladding vias 123 may be initially patterned at operations 518 or 750, thereafter metallized with cladding connections 116, and then extended or lengthened through the extended insulating layer 618 at operation 1106.

At operation 1108 and FIG. 12D, an adhesion layer 1240 and/or a seed layer 1242 are optionally formed on one or more surfaces of the insulating layer 618. In certain embodiments, the adhesion layer 1240 and the seed layer 1242 are substantially similar to the adhesion layer 1040 and the seed layer 1042, respectively. For example, the adhesion layer 1240 is formed from titanium, titanium nitride, tantalum, tantalum nitride, manganese, manganese oxide, molybdenum, cobalt oxide, cobalt nitride, or any other suitable materials or combinations thereof. In certain embodiments, the adhesion layer 1240 has a thickness between about 10 nm and about 300 nm, such as a thickness between about 50 nm and about 150 nm. For example, the adhesion layer 1240 has a thickness between about 75 nm and about 125 nm, such as about 100 nm. The adhesion layer 1240 may be formed by any suitable deposition process, including but not limited to CVD, PVD, PECVD, ALD, or the like.

The seed layer 1242 is formed from a conductive material such as copper, tungsten, aluminum, silver, gold, or any other suitable materials or combinations thereof. In certain embodiments, the seed layer 1242 has a thickness between about 0.05 μm and about 0.5 μm, such as between about 0.1 μm and about 0.3 μm. For example, the seed layer 1242 has a thickness between about 0.15 μm and about 0.25 μm, such as about 0.2 μm. Similar to the adhesion layer 1240, the seed layer 1242 may be formed by any suitable deposition process, such as CVD, PVD, PECVD, ALD dry processes, wet electroless plating processes, or the like. In certain embodiments, a molybdenum adhesion layer 1240 and a copper seed layer 1242 are formed on the intermediate core assembly 612 to reduce the formation of undercut during a subsequent seed layer etch process at operation 1122.

At operations 1110, 1112, and 1114, corresponding to FIGS. 12E, 12F, and 12G, respectively, a spin-on/spray-on or dry resist film 1250, such as a photoresist, is applied over the seeded surfaces of the intermediate core assembly 612 and subsequently patterned and developed. In certain embodiments, an adhesion promoter (not shown) is applied to the intermediate core assembly 612 prior to placement of the resist film 1250. The exposure and development of the resist film 1250 results in opening of the redistribution vias 1253, and in certain embodiments, cladding vias 123. Thus, patterning of the resist film 1250 may be performed by selectively exposing portions of the resist film 1250 to UV radiation, and subsequent development of the resist film 1250 by a wet process, such as a wet etch process. In certain embodiments, the resist film development process is a wet etch process utilizing a buffered etch process selective for a desired material. In other embodiments, the resist film development process is a wet etch process utilizing an aqueous etch process. Any suitable wet etchant or combination of wet etchants may be used for the resist film development process.

At operations 1116 and 1118, corresponding to FIGS. 12H and 121, respectively, redistribution connections 1244 are formed through the exposed redistribution vias 1253 and the resist film 1250 is thereafter removed. In certain embodiments, cladding connections 116 are also formed through the exposed cladding vias 123 at operation 1116. In certain embodiments, the resist film 1250 is removed via a wet process. As depicted in FIGS. 12H and 121, the redistribution connections 1244 fill the redistribution vias 1253 and may protrude from the surfaces of the intermediate core assembly 612 upon removal of the resist film 1250. In certain embodiments, the redistribution connections 1244 are formed of copper. In other embodiments, the redistribution connections 1244 are formed of any suitable conductive material including but not limited to aluminum, gold, nickel, silver, palladium, tin, or the like. Any suitable methods may be utilized to form the redistribution connections 1244, including electroplating and electroless deposition.

At operation 1120 and FIG. 12J, the intermediate core assembly 612 having the redistribution connections 1244 formed thereon is exposed to a seed layer etch process substantially similar to that of operation 970. In certain embodiments, the seed layer etch is a wet etch process including a rinse and drying of the intermediate core assembly 612. In certain embodiments, the seed layer etch process is a wet etch process utilizing a buffered etch process selective for a desired material of the seed layer 1242. In other embodiments, the etch process is a wet etch process utilizing an aqueous etch process. Any suitable wet etchant or combination of wet etchants may be used for the seed layer etch process.

Upon completion of the seed layer etch process at operation 1120, one or more additional redistribution layers 1260 may be formed on the intermediate core assembly 612 utilizing the sequences and processed described above, as shown in FIG. 12L. For example, one or more additional redistribution layers 1260 may be formed on the first redistribution layer 1260 and/or an opposing surface of the intermediate core assembly 612, such as major surface 1007. In certain embodiments, the one or more additional redistribution layers 1260 may be formed of polymer-based dielectric materials, such as a flowable build-up materials, that are different from the material of the first redistribution layer 1260 and/or the insulating layer 618. For example, in some embodiments, the insulating layer 618 may be formed of an epoxy filled with ceramic fibers, while the first and/or any additional redistribution layers 1260 are formed of polyimide, BCB, and/or PBO. Alternatively, or upon formation of a desired amount of redistribution layers 1260, at operation 1122 and FIG. 12K, one or more semiconductor core assemblies 1270 may be singulated from the intermediate core assembly 612 after a desired number of redistribution layers 1260 is formed.

The methods and structures described above with reference to FIGS. 1-12L relate to thin form factor package architectures having high I/O densities and relative small vertical dimensions, thus facilitating improved signal integrity and power delivery. As previously described, due to CTE mismatch between the components thereof, and/or the relatively long but narrow (e.g., thin) substrates utilized for such thin form factor package structures, unwanted substrate warpage and/or substrate collapse may occur during the assembling/fabrication thereof. Accordingly, the formation of a stiffener frame on the aforementioned package structures can reduce or eliminate the occurrence of warpage without negatively affecting overall package functionality.

FIG. 13 illustrates a flow diagram of a representative method 1300 of forming an fcBGA-type package structure having a stiffener frame 1410 utilizing, e.g., the intermediate core assembly 612 as described above, according to certain embodiments of the present disclosure. FIGS. 14A-14J schematically illustrate cross-sectional views of the intermediate core assembly 612 at different stages of the method 1300. For clarity, FIG. 13 and FIGS. 14A-14J are herein described together for clarity.

Note that although the operations of FIG. 13 and FIGS. 14A-14J are described as utilizing the intermediate core assembly 612, the methods thereof may be performed on previously singulated semiconductor core assemblies 1270 as well. Further, although FIG. 13 and FIGS. 14A-J are described with reference to forming a stiffener frame on an fcBGA-type package structure, the operations described below may also be performed on other types of devices, such as PCB assemblies, PCB spacer assemblies, chip carrier and intermediate carrier assemblies (e.g., for graphics cards), memory stacks, and the like.

The method 1300 generally begins with operation 1302 and FIG. 14A, wherein a solder mask 1466a is applied to a “frontside” or “device side” surface of the intermediate core assembly 612. For example, the solder mask 1466a is applied to major surface 1005 of the intermediate core assembly 612. Generally, the solder mask 1466a has a thickness between about 10 μm and about 100 μm, such as between about 15 μm and about 90 μm. For example, the solder mask 1466a has a thickness of between about 20 μm and about 80 μm.

In certain embodiments, the solder mask 1466a is a thermal-set epoxy liquid, which is silkscreened through a patterned woven mesh onto the insulating layer 618 on the device side of the intermediate core assembly 612. In certain embodiments, the solder mask 1466a is a liquid photo-imageable solder mask (LPSM) or liquid photo-imageable ink (LPI), which is silkscreened or sprayed onto the device side of the intermediate core assembly 612. The liquid photo-imageable solder mask 1466a is then exposed and developed in subsequent operations to form desired patterns. In other embodiments, the solder mask 1466a is a dry-film photo-imageable solder mask (DFSM), which is vacuum-laminated on the device side of the intermediate core assembly 612 and then exposed and developed in subsequent operations. In such embodiments, a thermal or ultraviolet cure is performed after a pattern is defined in the solder mask 1466a.

At operation 1304 and FIG. 14B, the intermediate core assembly 612 is flipped over and a second solder mask 1466b is applied to a “backside” or “non-device side” surface of the intermediate core assembly 612. For example, the solder mask 1466b is applied to major surface 1007 of the intermediate core assembly 612. Generally, the solder mask 1466b is substantially similar to solder mask 1466a, although in certain embodiments, the solder mask 1466b is a different type or material than solder mask 1466a, selected from the types/materials of solder masks described above.

At operation 1306 and FIG. 14C, the intermediate core assembly 612 is flipped back over, and solder mask 1466a is patterned to form vias 1403a therein. The vias 1403a expose desired interconnections 1044 and/or redistribution connections 1244 on the device side of the intermediate core assembly 612 for designated signal routing to outer surfaces of the package being fabricated.

In certain embodiments, solder mask 1466a may be patterned via the methods described above. In still other embodiments, the solder mask 1466a is patterned by, for example, laser ablation. In such embodiments, the laser ablation patterning process may be performed utilizing a CO₂ laser, a UV laser, or a green laser. For example, the laser source may generate a pulsed laser beam having a frequency between about 100 kHz and about 1000 kHz. In one example, the laser source is configured to deliver a pulsed laser beam at a wavelength of between about 100 nm and about 2000 nm, at a pulse duration between about 10E-4 ns and about 10E-2 ns, and with a pulse energy of between about 10 μJ and about 300 μJ.

At operation 1308 and FIG. 14D, the intermediate core assembly 612 is flipped over one again, and solder mask 1466b patterned to form vias 1403b therein. Similar to vias 1403a, the vias 1403b expose desired interconnections 1044 and/or redistribution connections 1244 on the intermediate core assembly 612 for designated signal routing to outer surfaces of the package being fabricated. Generally, solder mask 1466b may be formed via any of the methods described above, including laser ablation.

After patterning both sides of the intermediate core assembly 612 the intermediate core assembly 612 is transferred to a curing rack upon which the intermediate core assembly 612, having the solder masks 1466a, 1466b attached thereto, is fully cured at operation 1310 and FIG. 14E. In certain embodiments, the cure process is performed at a temperature of between about 80° C. and about 200° C. and for a period between about 10 minutes and about 80 minutes, such as a temperature of between about 90° C. and about 200° C. and for a period between about 20 minutes and about 70 minutes. For example, the cure process is performed at a temperature of about 180° C. for a period of about 30 minutes, or at a temperature of about 100° C. for a period of about 60 minutes. In further embodiments, the cure process at operation 1310 is performed at or near ambient (e.g., atmospheric) pressure conditions.

At operation 1312 and FIG. 14F, a plating process is performed over both device and non-device sides of the intermediate core assembly 612 to form conductive layers 1470a and 1470b on the device side (e.g., side including surface 1005, shown facing up) and non-device side (e.g., side including surface 1007, shown facing down) of the intermediate core assembly 612, respectively. As shown in FIG. 14F, the plated conductive layers 1470a, 1470b extend interconnections 1044 and/or redistribution connections 1244 through vias 1403a on the device side and vias 1403b on the non-device side to facilitate electrical connection thereof with other devices and/or package structures.

Each conductive layer 1470a and 1470b is formed of one or more metallic layers formed by electroless plating. For example, in certain embodiments, each conductive layer 1470a and 1470b includes an electroless nickel plating layer covered with a thin layer of gold and/or palladium formed by electroless nickel immersion gold (ENIG) or electroless nickel electroless palladium immersion gold (ENEPIG). However, other metallic materials and plating techniques are also contemplated, including soft ferromagnetic metal alloys and highly conductive pure metals. In certain embodiments, conductive layer 1470a and/or 1470b are formed of one or more layers of copper, chrome, tin, aluminum, nickel chrome, stainless steel, tungsten, silver, or the like.

In certain embodiments, each conductive layer 1470a and/or 1470b has a thickness between about 0.2 μm and about 20 μm, such as between about 1 μm and about 10 μm, on the device side or non-device side of the intermediate core assembly 612. During the plating of the conductive layer 1470a and 1470b, the exposed interconnections 1044 and/or redistribution connections 1244 are further extended outward from the intermediate core assembly 612 and through the solder masks 1466a, 1466b to facilitate further coupling with additional devices in subsequent fabrication operations.

At operation 1314 and FIG. 14G, a solder-on-pad (SOP) process is performed over both device and non-device sides of the intermediate core assembly 612 to form solder pads 1480a and 1480b on the device and non-device side of the intermediate core assembly 612, respectively. For example, in certain embodiments, solder is applied to vias 1403a, 1403b and then reflowed, followed by a flattening process such as coining to form substantially flat surfaces for solder pads 1480a, 13480b.

At operation 1316 and FIG. 14H, an adhesive 1490 is applied to desired areas/surfaces of the solder mask 1466a (e.g., on the device side) upon which by the stiffener frame 1410 is to be attached. In certain embodiments, adhesive 1490 includes a laminated adhesive material, die attach film, adhesive film, glue, wax, or the like. In certain embodiments, adhesive 1490 is a layer of dielectric material similar to that of insulating layer 618, such as an epoxy resin material having a ceramic filler. The adhesive 1490 may be applied to the solder mask 1466a by mechanical rolling, pressing, lamination, spin coating, doctor-blading, etc.

In certain embodiments, however, rather than applying the adhesive 1490 to the solder mask 1466a, the adhesive 1490 may be applied directly to the stiffener frame 1410, which may thereafter be attached to the solder mask 1466a of the intermediate core assembly 612. When using a die attach or adhesive film as the adhesive 1490 in such embodiments, the film may be trimmed to the lateral dimensions of the stiffener frame 1410 as the stiffener frame 1410 is structured/patterned.

After application of the adhesive 1490 onto the intermediate core assembly 612, the stiffener frame 1410 is attached to the adhesive 1490 at operation 1318 and FIG. 14I. As shown, the stiffener frame 1410 includes one or more openings 1417 within which semiconductor dies may be attached in subsequent operations. To form the openings 1417, the stiffener frame 1410 may be patterned prior to operation 1316 via the methods described above with reference to FIG. 3 and FIGS. 4A-4D.

At operation 1320 and FIG. 14J, one or more semiconductor dies 1420 are electrically coupled, via solder bumps 1424, to the solder pads 1480a exposed through openings 1417 on the device side of intermediate core assembly 612; a ball grid array (BGA) 1440 is mounted to solder pads 1480b on the non-device side; and the intermediate core assembly 612 is singulated into one or more electrically functioning fcBGA-type package devices 1400 (in embodiments where the operations of FIG. 13 and FIGS. 14A-14J are performed on singulated semiconductor core assemblies 1270, no further singulation is necessary). In certain embodiments, the BGA 1440 is formed via electrochemical deposition to form C4- or C2-type bumps. In certain embodiments, the semiconductor dies 1420 are coupled to the solder pads 1480a via a flip chip die attach process, wherein the semiconductor die 1420 is inverted and its contacts or bond pads 1422 are connected to solder pads 1480a. In certain examples, connection of contacts 1422 and solder pads 1480a is accomplished via mass reflow or thermo-compression bonding (TCB). In such examples, a capillary underfill, non-conductive paste, or non-conductive film may be laminated between semiconductor dies 1420 and the intermediate core assembly 612. In certain embodiments, the semiconductor die 1420 and/or BGA 1440 are coupled to the intermediate core assembly 612 prior to attachment of the stiffener frame 1410, and the intermediate core assembly 612 is singulated thereafter.

After singulation, each singulated package device 1400 may thereafter be integrated with other semiconductor devices and packages in various 2.5D and 3D arrangements and architectures, such as homogeneous or heterogeneous 3D stacked systems. Generally, when a stiffener frame, e.g., stiffener frame 1410, is incorporated into a package device 1400 that is then integrated in a larger stacked system, the beneficial reduction in warpage of the package device 1400 further extends to the overall system. That is, bolstering the structural integrity of the package device 1400, in turn, reduces the likelihood of warpage or collapse of the entire integrated system.

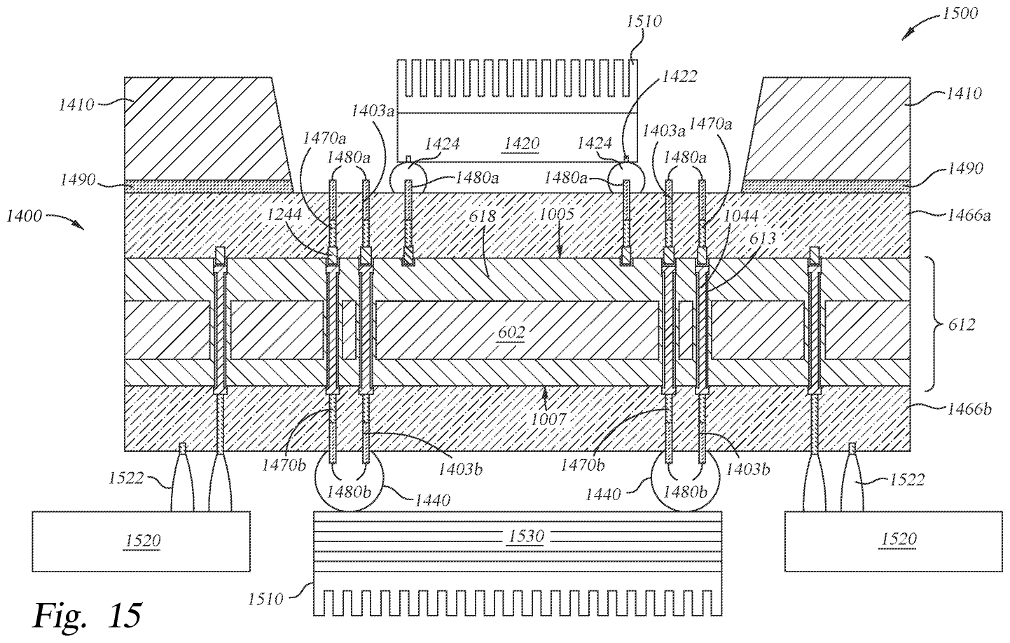

FIG. 15 schematically illustrates a cross-sectional side view of an example stacked system 1500 which integrates the package device 1400 having stiffener frame 1410 formed thereon, thereby improving the structural integrity of the system 1500, according to embodiments described herein. As shown, in addition to package device 1400, example system 1500 further includes one or more PCBs 1520, which may be vertically stacked or disposed side-by-side, a high bandwidth memory (HBM) module 1530 having large parallel interconnect densities between memory dies and central processing unit (CPU) cores or logic dies, and one or more heat exchangers 1510. In the example of FIG. 15, semiconductor die 1420 of the package device 1400 may be representative of a graphics processing unit (GPU), which is electrically coupled to HBM 1530 via interconnections 1044 disposed through core substrate 602, as well as solder bumps 1424 and BGA 1440. Package device 1400 may be electrically connected to PCBs 1520 via, e.g., redistribution connections 1244 formed on the non-device side thereof and pin connectors 1522 formed on the PCBs 1520.

The integration of the heat exchangers 1510, such as heat sinks, improves heat dissipation and thermal characteristics of the package device 1400, and thus, system 1500, by transferring heat that is conducted by e.g., the semiconductor die 1420, HBM 1530, and/or silicon core substrate 602. The improved heat dissipation, in turn, further the likelihood of warpage. Suitable types of heat exchangers 1510 include pin heat sinks, straight heat sinks, flared heat sinks, and the like, which may be formed of any suitable materials such as aluminum or copper. In certain embodiments, the heat exchangers 1510 are formed of extruded aluminum. In certain embodiments, the heat exchangers 1510 are attached directly to one or more semiconductor dies integrated within system 1500, such as semiconductor die 1420 and one or more dies of HBM module 1530, as shown in FIG. 15. In other embodiments, the heat exchangers 1510 are attached directly, or indirectly via insulating layer 618, to core substrate 602. Such arrangements are particular beneficial over conventional PCB's that are formed of glass-reinforced epoxy laminates having low thermal conductivity, to which the addition of a heat exchanger would be of little value.

FIG. 16 schematically illustrates a cross-sectional side view of a device configuration 1600 of the package device 1400 having at least one semiconductor die 1620 embedded therein, in addition to at least one semiconductor die 1420 stacked thereon, according to embodiments described herein. The semiconductor dies 1620 may be any suitable type of die or chip, including a memory die, a microprocessor, a complex system-on-a-chip (SoC), or a standard die. Suitable types of memory dies include DRAM dies or NAND flash dies. In further examples, the semiconductor dies 1620 include digital dies, analog dies, or mixed dies. Generally, the semiconductor dies 1620 may be formed of a material substantially similar to that of the core substrate 602, the semiconductor dies 1402, and/or the stiffener frame 110, such as a silicon material. Utilizing semiconductor dies 1620 formed of the same or similar materials of the core substrate 102, the semiconductor dies 1420, and/or the stiffener frame 110 facilitates matching of CTE therebetween, fundamentally eliminating the occurrence of warpage during assembly.

As shown in FIG. 16, each semiconductor die 1620 is disposed within a cavity 1603 formed in the core substrate 602 of package device 1400, and is further embedded therein by insulating layer 618 such that all sides thereof are in contact with insulating layer 618. The cavities 1603 may be formed in the core substrate 602 by the methods described above with reference to FIG. 3 and FIGS. 4A-4D (e.g., laser ablation), and the semiconductor dies 1620 may be placed in the cavities 1603 prior to lamination of insulating layer 618 over the cores substrate 602 (described above with reference to FIG. 5, FIGS. 6A-6I, FIG. 7, and FIGS. 8A-8E).

In certain embodiments, each cavity 1603 has lateral dimensions ranging between about 0.5 mm and about 50 mm, such as between about 3 mm and about 12 mm, such as between about 8 mm and about 11 mm, depending on the size and number of semiconductor dies 1620 to be embedded therein during device fabrication. In certain embodiments, the cavities 1603 are sized to have lateral dimensions substantially similar to that of the semiconductor dies 1620 embedded (e.g., integrated) therein. For example, each cavity 1603 is formed having lateral dimensions exceeding those of the semiconductor dies 1620 by less than about 150 μm, such as less than about 120 μm, such as less than 100 μm. Having a reduced variance in the size of the cavities 1603 and the semiconductor dies 1620 embedded therein reduces the amount of gap-fill dielectric material (e.g., insulating layer 618) necessitated thereafter.

After lamination of the insulating layer 618, through-assembly vias 613 may be formed in insulating layer 618 to expose one or more contacts 1622 of the semiconductor die 1620, and interconnections 1044 and/or redistribution connections 1244 may be, e.g., plated through the through-assembly vias 613 to electrically connect the semiconductor die 1620 to a surface of the package device 1400 (described above with reference to FIG. 9 and FIGS. 10A-10H) (here, semiconductor die 1620 is electrically routed to surface 1005 on the device side of package device 1400). The interconnections 1044 and/or redistribution connections 1244 may further be electrically coupled to one or more devices and/or systems via, e.g., solder bumps or the like. For example, as shown in FIG. 16, the interconnections 1044 and redistribution connections 1244 on the non-device side are electrically coupled to PCB 1520 via BGA 1440.

FIG. 17 schematically illustrates a cross-sectional side view of another device configuration 1700 of the package device 1400, according to embodiments described herein. As shown in FIG. 17, a lid 1710 is attached to the stiffener frame 1410 and covers the semiconductor dies 1420 stacked on and electrically coupled to the package device 1400. Some conventional integrated circuits, such as microprocessors or GPUs, generate substantial quantities of heat during operation that must be transferred away to avoid device damage or even shutdown. For such devices, the lid 1710 serves as a protective cover as well as a heat transfer pathway. Furthermore, the lid 1710 provides additional structural reinforcement for the package device 1400, which already includes the stiffener frame 1410 formed thereon. Thus, the device configuration 1700 facilitates improved heat dissipation and thermal characteristics, as well as improved structural integrality, as compared to conventional package structures.

Generally, the lid 1710 has a polygonal or circular ring-like shape and is formed from a patterned substrate comprising any suitable substrate material. In certain embodiments, the lid 1710 may be formed from a substrate comprising a material substantially similar to that of the stiffener frame 1410 and core substrate 602, thus matching the coefficient of thermal expansion (CTE) thereof and reducing or eliminating the risk of warpage of device configuration 1700 during assembly. For example, the lid 1710 may be formed from a III-V compound semiconductor material, silicon (e.g., having a resistivity between about 1 and about 10 Ohm-com or conductivity of about 100 W/mK), crystalline silicon (e.g., Si<100> or Si<111>), silicon oxide, silicon germanium, doped or undoped silicon, undoped high resistivity silicon (e.g., float zone silicon having lower dissolved oxygen content and a resistivity between about 5000 and about 10000 ohm-cm), doped or undoped polysilicon, silicon nitride, silicon carbide (e.g., having a conductivity of about 500 W/mK), quartz, glass (e.g., borosilicate glass), sapphire, alumina, and/or ceramic materials. In certain embodiments, the lid 1710 includes monocrystalline p-type or n-type silicon. In certain embodiments, the lid 1710 includes polycrystalline p-type or n-type silicon.

The lid 1710 has a thickness T₄ between about 50 μm and about 1500 μm, such as a thickness T₄ between about 100 μm and about 1200 μm. For example, the lid 1710 has a thickness T₄ between about 200 μm and about 1000 μm, such as a thickness T₄ between about 300 μm and about 775 μm, such as a thickness T₄ of about 750 μm or 775 μm. In another example, the lid 1710 has a thickness T₄ between about 100 μm and about 700 μm, such as a thickness T₄ between about 200 μm and about 500 μm. In another example, the lid 1710 has a thickness T₄ between about 800 μm and about 1400 μm, such as a thickness T₄ between about 1000 μm and about 1200 μm. In yet another example, the lid 1710 has a thickness T₄ greater than about 1200 μm.

The lid 1710 is attached to the stiffener frame 1410 via any suitable methods. For example, as shown in FIG. 17, the lid 1710 may be attached to the stiffener frame 1410 via an adhesive 1790, which may include a laminated adhesive material, die attach film, adhesive film, glue, wax, or the like. In certain embodiments, adhesive 1790 is a layer of uncured dielectric material similar to that of insulating layer 618, such as an epoxy resin material having a ceramic filler.

In addition to being attached to the stiffener frame 1410, the lid 1710 is also indirectly attached to the semiconductor dies 1420 via a thermal interface material (TIM) layer 1792 in order to provide a heat transfer pathway for the semiconductor dies 1420. Generally, the TIM layer 1792 eliminates air gaps or spaces between the semiconductor dies 1420 and the lid 1720 to eliminate air gaps or spaces, which act as thermal insulation, from the interface therebetween in order to maximize heat transfer and dissipation. In certain embodiments, the TIM layer 1792 includes a thermal paste, a thermal adhesive (e.g., a glue), a thermal tape, an underfill material, or a potting compound. In certain embodiments, the TIM layer 1792 is a thin layer of flowable dielectric material substantially similar to that of the insulating layer 618, such as a flowable epoxy resin with an aluminum oxide or nitride filler.

In sum, the methods and device architectures described herein provide multiple advantages over semiconductor packaging methods and architectures implementing conventional stiffening techniques, such as the incorporation of metal stiffening layers (e.g., dummy copper stiffening layer) that may produce an unwanted antenna effect, stitching ground vias, etc. Such advantages include the construction of, e.g., flip-chip type BGA package structures with matching CTEs between integrated (e.g., embedded or stacked) silicon semiconductor dies, silicon substrate cores, as well as the silicon stiffener frame, thus significantly reducing or eliminating warpage during assembly and processing. The utilization of the stiffener frames described herein further enables greater chip-to-substrate bump-pitch scaling with thinner but wider package substrates for high performance computing (HPC) applications. Because the stiffener frames may be patterned by silicon substrate structuring methods, the stiffener frames may be readily integrated with current packaging assembly methods, thus producing a cost- and time-efficient warpage mitigation solution.

While the foregoing is directed to embodiments of the present disclosure, other and further embodiments of the disclosure may be devised without departing from the basic scope thereof, and the scope thereof is determined by the claims that follow.

What is claimed is:

1. A semiconductor device assembly, comprising:
a silicon core comprising:
a first side opposing a second side,
wherein the silicon core has a via through the silicon core from the first side to the second side;
an oxide layer on the first side and the second side; and
one or more conductive interconnections through the via and having a surface exposed at the first side and the second side;
an insulating layer over the oxide layer on the first side, the second side, and within the via;
a first redistribution layer on the first side; and
a silicon stiffener frame over the insulating layer and the first redistribution layer on the first side, an outer surface of the stiffener frame disposed substantially along a perimeter of the semiconductor device assembly.

2. The semiconductor device assembly of claim 1, wherein the silicon stiffener frame is formed of substantially the same material as the silicon core.

3. The semiconductor device assembly of claim 1, wherein the silicon stiffener frame has a coefficient of thermal expansion (CTE) substantially matching a CTE of the silicon core.

4. The semiconductor device assembly of claim 1, wherein the silicon stiffener frame has an opening formed therein.

5. The semiconductor device assembly of claim 4, wherein the semiconductor device assembly further comprises a first semiconductor die disposed within the opening of the silicon stiffener frame.

6. The semiconductor device assembly of claim 5, wherein the first semiconductor die is electrically coupled to one or more contacts of the redistribution layer by flip-chip attachment.

7. The semiconductor device assembly of claim 5, wherein the silicon stiffener frame has a coefficient of thermal expansion (CTE) substantially matching a CTE of the silicon core and a CTE of the first semiconductor die.

8. The semiconductor device assembly of claim 5, further comprising a second semiconductor die electrically coupled to one or more electrical contacts on the second side of the semiconductor device assembly by a ball grid array (BGA).

9. The semiconductor device assembly of claim 1, wherein the silicon core has a thickness less than about 200 μm, and wherein the stiffener frame has a thickness greater than about 500 μm.

10. The semiconductor device assembly of claim 1, wherein the silicon stiffener frame has a metal layer formed over one or more surfaces thereof.

11. The semiconductor device assembly of claim 10, wherein the metal layer comprises nickel.

12. The semiconductor device assembly of claim 1, further comprising a semiconductor die disposed within a cavity of the silicon core and embedded within the insulating layer, wherein 6 or more surfaces of the semiconductor die are in contact with the insulating layer.

13. A semiconductor device assembly, comprising:
a silicon core comprising:
a first side opposing a second side,
wherein the silicon core has a via extending through the silicon core from the first side to the second side;
a metal layer on the first side and the second side and electrically coupled to ground; and
one or more conductive interconnections through the via and having a surface exposed at the first side and the second side;
an insulating layer over the metal layer on the first side, the second side, and within the via;
a first redistribution layer on the first side; and
a silicon stiffener frame over the insulating layer and the first redistribution layer on the first side, an outer surface of the stiffener frame disposed substantially along a perimeter of the semiconductor device assembly.

14. The semiconductor device assembly of claim 13, wherein the silicon stiffener frame is formed of substantially the same material as the silicon core.

15. The semiconductor device assembly of claim 14, wherein the silicon stiffener frame has a coefficient of thermal expansion (CTE) substantially matching a CTE of the silicon core.

16. The semiconductor device assembly of claim 13, wherein the silicon stiffener frame has an opening formed therein.

17. The semiconductor device assembly of claim 16, wherein the semiconductor device assembly further comprises a first semiconductor die disposed within the opening of the silicon stiffener frame.

18. The semiconductor device assembly of claim 17, wherein the first semiconductor die is electrically coupled to one or more contacts of the redistribution layer by flip-chip attachment.

19. The semiconductor device assembly of claim 17, wherein the silicon stiffener frame has a coefficient of thermal expansion (CTE) substantially matching a CTE of the silicon core and a CTE of the first semiconductor die.

20. A semiconductor device assembly, comprising:
a silicon core comprising:
a first side opposing a second side,
wherein the silicon core has a via extending through the silicon core from the first side to the second side;
an oxide layer on the first side and the second side; and
one or more conductive interconnections through the via and having a surface exposed at the first side and the second side;
an insulating layer over the oxide layer on the first side, the second side, and within the via;
a first redistribution layer on the first side; and
a silicon stiffener frame contacting the oxide layer on the first side of the silicon core, an outer surface of the stiffener frame disposed substantially along a perimeter of the silicon core.
